(19) United States
(12) Patent Application Publication
(10) Pub. No.: US 2013/0337648 A1
(43) Pub. Date: Dec. 19, 2013

(54) METHOD OF MAKING CAVITY SUBSTRATE WITH BUILT-IN STIFFENER AND CAVITY

(71) Applicant: Bridge Semiconductor Corporation, Taipei City (TW)

(72) Inventors: Charles W.C. LIN, Singapore (SG); Chia-Chung WANG, Hsinchu (TW)

(21) Appl. No.: 13/904,207

(22) Filed: May 29, 2013

Related U.S. Application Data
(60) Provisional application No. 61/659,491, filed on Jun. 14, 2012.

(51) Int. Cl. H01L 21/48

(52) U.S. Cl. CPC H01L 21/486
USPC 438/675

(57) ABSTRACT

The present invention relates to a method of making a cavity substrate. In accordance with a preferred embodiment, the method includes: providing a sacrificial carrier and optionally an electrical pad that extends from the sacrificial carrier in the first vertical direction; providing a dielectric layer that covers the sacrificial carrier in the first vertical direction; removing a selected portion of the sacrificial carrier; attaching a stiffener to the dielectric layer from the second vertical direction; forming a build-up circuitry from the first vertical direction; and removing the remaining portion of the sacrificial carrier to expose electrical contacts from the second vertical direction. A semiconductor device can be mounted on the cavity substrate and electrically connected to the electrical contacts within the built-in cavity of the cavity substrate. The stiffener can provide mechanical support for the build-up circuitry and the semiconductor device.

### CROSS REFERENCE TO RELATED APPLICATION

This application claims the benefit of filing date of U.S. Provisional Application Ser. No. 61/659,491, entitled “Cavity Substrate with Electrical Contacts Exposed from Cavity and Stackable Semiconductor Assembly Using the Same and Method of Making the Same” filed Jun. 14, 2012 under 35 USC §119(e)(1).

### BACKGROUND OF THE INVENTION

1. Field of the Invention

The present invention relates to a method of making a cavity substrate, and more particularly to a method of making a cavity substrate with one or more electrical contacts exposed from a built-in cavity.

2. Description of Related Art

Latest trends of electronic devices such as mobile internet devices (MIDs), multimedia devices and computer notebooks demand for faster and slimmer designs. In the frequency band of a general signal, the shorter paths of circuitry, the better the signal integrity. Thus, the size of inter-layer connection, i.e., the diameter of the micro-via and plated through hole in the substrate must be reduced in order to improve the signal delivery characteristic of the electronic component. As plated-through-hole in the copper-clad laminate core is typically formed by mechanical CNC drill, reducing its diameter in order to increase wiring density may encounter seriously technical limitations and often very costly. As such, coreless substrates are proposed for packaging substrate to enable a thinner, lighter and faster design of the components. However, as coreless boards do not have a core layer to provide a necessary flexural rigidity, they are more susceptible to warpage problem when under thermal stress compared to that of conventional boards with core layers.

U.S. Pat. No. 7,164,198 to Nakamura et al., U.S. Pat. No. 7,400,035 to Abe et al., U.S. Pat. No. 7,582,961 to Chia et al., U.S. Pat. No. 7,934,313 to Lin et al. disclose a coreless packaging substrate with built-in stiffener by etching a portion of a metal sheet on which the build-up circuitry is formed. The built-in stiffener defines a cavity which serves as the region for semiconductor device attachment. In this approach, although a supporting platform can be created and warping issues may be improved, etching a thick metal block is prohibitively cumbersome, low throughput, and prone to create many yield-loss issues such as an uncontrollable boundary line due to etching under-cut.

U.S. Pat. No. 8,108,993 to Higashi et al. discloses a method to form built-in stiffener by using a supporting substrate on which the build-up circuitry is formed. In this approach, a peeling promotion layer is applied on the supporting substrate so that the build-up layers can be separated from the supporting substrate after the coreless wiring board is finished. Since the peeling promotion layer, either a thermal setting resin or an oxide film, has the peeling off property when under a heat or light treatment, there exists a high risk of early delamination during dielectric layer coating and curing, this may result in serious yield and reliability concerns.

In view of the various development stages and limitations in currently available coreless substrate for high I/O and high performance semiconductor devices, there is a need for a packaging board that can provide optimize signal integrity, maintain low warping during assembly and operation, and low cost manufacturing.

### SUMMARY OF THE INVENTION

The present invention has been developed in view of such a situation, and an object thereof is to provide a cavity substrate in which a built-in stiffener can provide mechanical support for the cavity substrate, and electrical contacts exposed from a built-in cavity can provide an electrical connection for an electrical device that extends into the cavity.

In one preferred embodiment, the present invention provides a method of making a cavity substrate that includes a build-in stiffener and a build-up circuitry with an electrical pad exposed from a cavity. The method for making the cavity substrate can include: providing a sacrificial carrier and an electrical pad that extends from the sacrificial carrier in a first vertical direction; providing a dielectric layer that covers the sacrificial carrier and the electrical pad in the first vertical direction; removing a selected portion of the sacrificial carrier with a remaining portion of the sacrificial carrier covering the electrical pad and a predetermined area for creating a cavity in a second vertical direction opposite the first vertical direction; attaching a stiffener to the dielectric layer from the second vertical direction, including aligning the remaining portion of the sacrificial carrier within an aperture of the stiffener; forming a build-up circuitry that covers the sacrificial carrier and the electrical pad in the first vertical direction and is electrically connected to the electrical pad; and removing the remaining portion of the sacrificial carrier to form the cavity and exposing the electrical pad and portion of the build-up circuitry at a closed end of the cavity from the second vertical direction, wherein the cavity is laterally covered and surrounded by the stiffener and faces in the second vertical direction.

In another preferred embodiment, the present invention provides a method for making a cavity substrate that includes a build-in stiffener and a build-up circuitry with portion of the build-up circuitry exposed from a cavity. The method for making the cavity substrate can include: providing a sacrificial carrier; providing a dielectric layer that covers the sacrificial carrier in a first vertical direction; removing a selected portion of the sacrificial carrier with a remaining portion of the sacrificial carrier covering a predetermined area for creating a cavity in a second vertical direction opposite the first vertical direction; attaching a stiffener to the dielectric layer from the second vertical direction, including aligning the remaining portion of the sacrificial carrier within an aperture of the stiffener; forming a build-up circuitry that covers the sacrificial carrier in the first vertical direction; and removing the remaining portion of the sacrificial earner to form the cavity and exposing portion of the build-up circuitry at a closed end of the cavity from the second vertical direction, wherein the cavity is laterally covered and surrounded by the stiffener and faces in the second vertical direction. In accordance with this preferred embodiment, exposing portion of the build-up circuitry can include exposing one or more conductive vias of the build-up circuitry.

In yet another preferred embodiment, the present invention provides a method for making a cavity substrate that includes a build-in stiffener and an interconnect substrate with a selected portion of the interconnect substrate exposed from the cavity. The method for making the cavity substrate can include: providing a sacrificial carrier; attaching an interconnect substrate to the sacrificial carrier using a dielectric layer that covers the sacrificial carrier in a first vertical direction and covers the interconnect substrate in a second vertical direction opposite the first vertical direction; removing a selected portion of the sacrificial carrier with a remaining portion of the sacrificial carrier covering a predetermined area for creating a cavity in the second vertical direction; attaching a stiffener to the dielectric layer from the second vertical direction, including aligning the remaining portion of the sacrificial carrier within an aperture of the stiffener; removing the remaining portion of the sacrificial carrier to form the cavity and exposing portion of the dielectric layer at a closed end of the cavity from the second vertical direction, wherein the cavity is laterally covered and surrounded by the stiffener and faces in the second vertical direction; and forming a via opening in the dielectric layer to expose a selected portion of the interconnect substrate at the closed end of the cavity from the second vertical direction. In accordance with this preferred embodiment, the via opening can extend through the dielectric layer and be aligned with and adjacent to a selected portion of a circuitry layer of the interconnect substrate.

The build-up circuitry can include a first insulating layer and one or more first conductive traces. For instance, the first insulating layer covers the sacrificial carrier in the first vertical direction and the first conductive traces extend from the first insulating layer in the first vertical direction. As a result, forming the build-up circuitry can include: providing a first insulating layer that includes the dielectric layer and covers the sacrificial carrier and the electrical pad if present in the first vertical direction; then forming one or more first via openings that extend through the first insulating layer and are aligned with the electrical pad or the sacrificial carrier and optionally with the stiffener; and then forming one or more first conductive traces that extend from the first insulating layer in the first vertical direction and extend laterally on the first insulating layer and extend through the first via openings in the second vertical direction to form one or more first conductive vias in contact with the electrical pad or the sacrificial carrier and optionally with the stiffener. Accordingly, the first conductive traces can directly contact the electrical pad to provide electrical connection between the build-up circuitry and the electrical pad that can serve as electrical contacts exposed from the cavity. Alternatively, selected portions of the first conductive traces can be exposed from the cavity and serve as electrical contacts to provide signal routing for an electronic device within the cavity. For instance, the first conductive vias of the build-up circuitry can be exposed from the cavity and serve as electrical contacts for an electronic device packaged in the cavity substrate. Additionally, the first conductive traces can also directly contact the stiffener for grounding or electrical connections to a conductive layer or passive components such as thin film resistors or capacitors deposited thereon.

The build-up circuitry can further include additional insulating layers, additional via openings, and additional conductive traces if needed for further signal routing. For instance, the build-up circuitry can further include a second insulating layer and one or more second conductive traces. The second insulating layer extends from the first insulating layer and the first conductive traces in the first vertical direction and includes one or more second via openings aligned with the first conductive traces. The second conductive traces extend from the second insulating layer in the first vertical direction and extend laterally on the second insulating layer and extend into the second via openings in the second vertical direction to form one or more second conductive vias in electrical contact with the first conductive traces. The first conductive vias and the second conductive vias can have the same size, and the first insulating layer, the first conductive traces, the second insulating layer and the second conductive traces can have flat elongated surfaces that face in the first vertical direction. The insulating layers of the build-up circuitry can extend to peripheral edges of the cavity substrate, and the conductive traces can provide horizontal signal routing and vertical routing through the via openings in the insulating layers.

Forming the first conductive trace can include depositing a plated layer on the first insulating layer that extends through the first via opening to form the first conductive via and then removing selected portions of the plated layer using an etch mask that defines the first conductive trace.

The interconnect substrate can include one or more circuitry layers. The circuitry layer can laterally extend on an insulating layer, and two neighboring circuitry layers spaced from one another by an insulating layer can be electrically connected to one another by one or more conductive vias. The insulating layer can extend to peripheral edges of the interconnect substrate, and the conductive vias can extend through the insulating layer to provide electrical connections between the circuitry layers. For instance, the interconnect substrate can include a first circuitry layer, a first insulating layer, one or more first conductive vias and a second circuitry layer. The first insulating layer is disposed between the first circuitry layer and the second circuitry layer and extends to peripheral edges of the interconnect substrate. The first conductive vias extend through the first insulating layer and are adjacent to the first circuitry layer and the second circuitry layer to provide electrical connections between the first circuitry layer and the second circuitry layer. Alternatively, the interconnect substrate can further include additional insulating layer, additional conductive vias, and additional circuitry layers if needed for further signal routing. For instance, the interconnect substrate can further include a second insulating layer, one or more second via openings and a third circuitry layer. The second insulating layer is disposed between the second circuitry layer and the third circuitry layer and extends to peripheral edges of the interconnect substrate. The second conductive vias extend through the second insulating layer and are adjacent to the second circuitry layer and the third circuitry layer to provide electrical connections between the second circuitry layer and the third circuitry layer. The first conductive vias and the second conductive vias can have the same size, and the first circuitry layer, the first insulating layer, the second circuitry layer, the second insulating layer and the third circuitry layer can have flat elongated surfaces that face in the first vertical direction.

The outmost conductive traces of the build-up circuitry and the outmost circuitry layer of the interconnect substrate can include one or more interconnect pads to provide electrical contacts for the next level assembly or another electronic device such as a semiconductor chip, a plastic package or another semiconductor assembly. The interconnect pads can include an exposed contact surface that faces in the first vertical direction. As a result, the next level assembly or another electronic device can be electrically connected to the build-up circuitry or the interconnect substrate using a wide variety of connection media including wire bonding or solder bumps as the electrical contacts.

The method of making the cavity substrate with the interconnect substrate can further include forming a conductive via in the via opening of the dielectric layer. The conductive via can extend from the interconnect substrate in the second vertical direction and include an exposed contact surface that faces in the second vertical direction. For instance, the conductive via can contact and extend from the first circuitry layer of the interconnect substrate in the second vertical and be coplanar with or lower than the dielectric layer in the second vertical direction.

The method of making a cavity substrate according to the present invention can further include providing a plated through-hole that extends through the stiffener to provide an electrical connection between both sides of the cavity substrate. For instance, the method of making the cavity substrate according to the present invention can further include: providing a terminal that extends from the stiffener in the second vertical direction; and providing a plated through-hole that extends through the stiffener to provide an electrical connection between the terminal and the build-up circuitry or between the terminal and the interconnect substrate.

Providing the terminal can include: depositing a plated layer that extends from the stiffener in the second vertical direction; and removing a selected portion of the plated layer. In the case that the stiffener includes a conductive layer thereon, removing a selected portion of the plated layer can include simultaneously removing the conductive layer that is covered by the plated layer in the second vertical direction. That is, the terminal can have a combined thickness of the conductive layer and the plated layer. The plated layer of the terminal can be simultaneously deposited during depositing conductive traces of build-up circuitry. Moreover, in consideration of process efficiency, the terminal can be simultaneously defined during the step of removing the remaining portion of the sacrificial carrier. That is, removing the remaining portion of the sacrificial carrier can include simultaneously removing a selected portion of the plated layer to define the terminal. The terminal can include an exposed contact surface that faces in the second vertical direction and can be used for grounding or serve as an electrical contact for the next level assembly or another electronic device.

Providing the plated through-hole can include: forming a through-hole that extends through the stiffener in the vertical directions; and then providing a connecting layer on an inner sidewall of the through-hole. As a result, the plated through-hole can provide an electrical connection between the build-up circuitry and the terminal or between the interconnect substrate and the terminal.

The through-hole can be provided after attaching the stiffener, and the connecting layer of the plated through-hole can be simultaneously deposited during depositing the plated layer of the terminal and outer or inner conductive traces of build-up circuitry. The plated through-hole can extend through the stiffener and one or more insulating layers of build-up circuitry in the vertical directions for the cavity substrate with the build-up circuitry, or extend through the stiffener, the dielectric layer and one or more insulating layers of the interconnect substrate in the vertical directions for the cavity substrate with the interconnect substrate.

In accordance with one aspect of the present invention, the method of making the cavity substrate with the build-up circuitry can include: providing a sacrificial carrier and optionally one or more electrical pads that extend from the sacrificial carrier in the first vertical direction; then providing a dielectric layer that covers sacrificial carrier and the electrical pads in the first vertical direction; then removing a selected portion of the sacrificial carrier; then attaching a stiffener to the dielectric layer from the second vertical direction; then forming one or more through-holes that extend through the stiffener and the dielectric layer in the vertical directions; then depositing a connecting layer on the inner sidewall of the through-holes; then forming one or more first via openings in the dielectric layer, wherein the first via openings are aligned with the electrical pads or the sacrificial carrier; then providing one or more first conductive traces that extend from the dielectric layer in the first vertical direction and extend laterally on the dielectric layer and extend through the first via openings of the dielectric layer in the second vertical direction to form one or more first conductive vias in contact with the electrical pads or the sacrificial carrier; and then removing the remaining portion of the sacrificial carrier. In this case, the plated through-hole can extend through the stiffener and one insulating layer in the vertical directions.

In accordance with another aspect of the present invention, the method of making the cavity substrate with the build-up circuitry can include: providing a sacrificial carrier and optionally one or more electrical pads that extend from the sacrificial carrier in the first vertical direction; then providing a dielectric layer that covers sacrificial carrier and the electrical pads in the first vertical direction; then removing a selected portion of the sacrificial carrier; then attaching a stiffener to the dielectric layer from the second vertical direction; then forming one or more first via openings in the dielectric layer, wherein the first via openings are aligned with the electrical pads or the sacrificial carrier; providing one or more first conductive traces that extend from the dielectric layer in the first vertical direction and extend laterally on the dielectric layer and extend through the first via openings in the second vertical direction to form one or more first conductive vias in contact with the electrical pads or the sacrificial carrier; forming one or more through-holes that extend through the stiffener and one or more insulating layers that include the dielectric layer in the vertical directions; providing a connecting layer on the inner sidewall of the through-holes; and then removing the remaining portion of the sacrificial carrier. In this case, the plated through-hole can extend through the stiffener and one or multiple insulating layer in the vertical directions, and the connecting layer of the plated through-hole can be provided during providing the first conductive trace or an additional conductive trace.

In accordance with yet another aspect of the present invention, the method of making the cavity substrate with the interconnect substrate can include: providing a sacrificial carrier; then attaching an interconnect substrate to the sacrificial carrier using a dielectric layer, wherein the interconnect substrate can include a first circuitry layer, a metal layer, a first insulating layer between the first circuitry layer and the metal layer, and one or more first conductive vias that extend through the first insulating layer; then removing a selected portion of the sacrificial carrier; then attaching a stiffener to the dielectric layer from the second vertical direction; then forming one or more through-holes that extend through the stiffener, the dielectric layer and the interconnect substrate in the vertical directions; then depositing a connecting layer on the inner sidewall of the through-holes; then removing the remaining portion of the sacrificial carrier; then forming one or more via openings in the dielectric layer, wherein the via openings are aligned with selected portions of the first circuitry layer of the interconnect substrate; and then optionally forming one or more conductive vias in the via openings. In this case, the plated through-hole can extend through the stiffener, the dielectric layer, the first insulating layer and the metal layer, and electrically connect a conductive layer of the stiffener to the metal layer of the interconnect substrate. After providing the plated through-hole, the metal layer of the interconnect substrate can be patterned to form an outer circuitry layer that can be electrically connected to the first circuitry layer through the first conductive vias and electrically connected to the terminal through the plated through-hole. In consideration of process efficiency, the metal layer can be simultaneously patterned during the step of removing the remaining portion of the sacrificial carrier. Alternatively, the metal layer is patterned after all metal deposition steps are accomplished. For instance, the metal layer can be patterned after the conductive vias are deposited in the via openings of the dielectric layer.

Accordingly, the plated though-hole at a first end can extend to and be electrically connected to an outer circuitry of the build-up circuitry or the interconnect substrate and at a second end can extend to and be electrically connected to the terminal. Alternatively, the plated through-hole at the first end can extend to and be electrically connected to an inner circuitry of the build-up circuitry. In any case, the plated through-hole can extend vertically through the stiffener and be in an electrically conductive path between the terminal and the build-up circuitry or between the terminal and the interconnect substrate.

Removing a selected portion of the sacrificial carrier can include photolithography and chemical etching process and can be performed in any step after providing the dielectric layer. The remaining portion of the sacrificial carrier can prevent adhesive overflow to the predetermined area for creating the cavity during the next step of attaching the stiffener to the dielectric layer using an adhesive.

Removing the remaining portion of the sacrificial carrier can include chemical etching process and preferably is performed after all metal deposition steps are accomplished such that the remaining portion of the sacrificial carrier can serve as barrier against metal deposition onto the electrical contacts (e.g. the electrical pads, the conductive vias of the build-up circuitry) located at the predetermined area for creating the cavity. In consideration of process efficiency, the remaining portion of the sacrificial carrier can be simultaneously removed during the patterning process for forming the terminal and/or the circuitry traces.

The dielectric layer and insulating layers can be deposited and extend to peripheral edges of the cavity substrate by numerous techniques including film lamination, roll coating, spin coating and spray-on deposition. The via openings can be formed by numerous techniques including laser drilling, plasma etching and photolithography. The through-hole can be formed by numerous techniques including mechanical drilling, laser drilling and plasma etching with or without wet etching. The plated layers, the connecting layer of the plated through-hole and the conductive vias in the via openings of the dielectric layer can be deposited by numerous techniques including electroplating, electroless plating, evaporating, sputtering, and their combinations as a single layer or multiple layers. The plated layers can be patterned by numerous techniques including wet etching, electro-chemical etching, laser-assist etching, and their combinations to define the conductive traces and the terminal.

The sacrificial carrier can be made of any material with good processability and good removability. For instance, the sacrificial carrier can be copper, aluminum, nickel, iron, tin or their alloys. The sacrificial carrier can be processed into a metal block with a circular, square or rectangular periphery. The metal block can extend into the aperture of the stiffener. In consideration of the electrical pad or the conductive via adjacent to the metal block not being etched during removal of the metal block, the sacrificial carrier may be made of a material such as tin or stainless steel that can be removed using an etching solution inactive to the electrical pad or the conductive via. Alternatively, the electrical pad can be made of any stable material against etching during removal of the metal block. For instance, the electrical pads may be gold pads in the case of the sacrificial carrier being made of copper. Moreover, the sacrificial carrier may further include a barrier layer such as Sn layer on its surface. For instance, the sacrificial carrier can be a copper sheet with a tin layer as a barrier layer thereon, such that the tin layer can protect the electrical pad or the conductive via from etching during removal of the copper sheet even the electrical pad or the conductive via being made of copper. The barrier layer can be made of any material that can be effectively removed without damage on the electrical pad or the conductive via. However, even though no barrier layer is applied or the metal block is made of the same material as the electrical pad or the conductive via as above mentioned, the outcome of the electrical pad or the conductive via being slightly etched during removal of the metal block is also acceptable and even better.

By the above-mentioned method, the present invention can provide a cavity substrate that includes one or more electrical contacts exposed from a cavity.

In accordance with one aspect of the present invention, the cavity substrate can include a cavity, an adhesive, a stiffener, an electrical pad and a build-up circuitry, wherein (i) the cavity has a closed end in the first vertical direction and an open end in the second vertical direction; (ii) the stiffener includes an aperture, wherein the cavity extends into the aperture; (iii) the adhesive laterally covers and surrounds and conformally coats a sidewall of the cavity, extends laterally from the cavity to peripheral edges of the substrate and covers and contacts the stiffener in the first vertical direction; (iv) the electrical pad extends from the closed end of the cavity in the first vertical direction; and (v) the build-up circuitry covers the electrical pad, the closed end of the cavity and adhesive in the first vertical direction and is coplanar with or higher than the electrical pad at the closed end of the cavity and is electrically connected to the electrical pad.

In accordance with another aspect of the present invention, the cavity substrate can include a cavity, an adhesive, a stiffener and a build-up circuitry, wherein (i) the cavity has a closed end in the first vertical direction and an open end in the second vertical direction; (ii) the stiffener includes an aperture, wherein the cavity extends into the aperture; (iii) the adhesive laterally covers and surrounds and conformally coats a sidewall of the cavity, extends laterally from the cavity to peripheral edges of the substrate and covers and contacts the stiffener in the first vertical direction; and (iv) the build-up circuitry covers the closed end of the cavity and adhesive in the first vertical direction and includes a conductive via that is exposed from the cavity in the second vertical direction.

In accordance with yet another aspect of the present invention, the cavity substrate can include a cavity, an adhesive, a stiffener, a dielectric layer, an interconnect substrate and optionally one or more conductive vias, wherein (i) the cavity has a closed end in the first vertical direction and an open end in the second vertical direction; (ii) the stiffener includes an aperture, wherein the cavity extends into the aperture; (iii) the adhesive laterally covers and surrounds and conformally coats a sidewall of the cavity, extends laterally from the cavity to peripheral edges of the substrate and covers and contacts the stiffener in the first vertical direction; (iv) the dielectric layer covers the closed end of the cavity and adhesive in the first vertical direction and includes one or more via openings that are aligned with the cavity; (iv) the interconnect substrate covers the dielectric layer in the first vertical direction and includes a circuitry layer that is adjacent to the via openings; and (v) the conductive vias contact and extend from the circuitry layer of the interconnect substrate into the via openings of the dielectric layer in the second vertical direction.

The stiffener can extend to peripheral edges of the cavity substrate to provide mechanical support for the build-up circuitry or the interconnect substrate and can be made of organic materials such as copper-clad laminate. The stiffener can also be made of inorganic materials such as aluminum oxide (Al₂O₃), aluminum nitride (AlN), silicon nitride (SiN), silicon (Si), copper (Cu), aluminum (Al), stainless steel, etc. Alternatively, the stiffener can be a single layer structure or a multi-layer structure such as a circuit board or a multi-layer ceramic board or a laminate of a substrate and a conductive layer.

The adhesive between the stiffener and the dielectric layer can extend to peripheral edges of the cavity substrate and extend into a gap located in the aperture between the stiffener and the metal block and conformally coat the sidewall of the cavity. Accordingly, the adhesive can have a first thickness where it is adjacent to the sidewall of the cavity and a second thickness where it covers the stiffener in the first vertical direction that is different from the first thickness. The adhesive can be made of the materials that are at least one selected from the group consisting of epoxy resin, bismaleimide triazine (BT), benzocyclobutene (BCB), Ajinomoto build-up film (ABF), liquid crystal polymer, polyimide, poly(phenylene ether), poly(tetrafluorothylene), aramide and glass fiber.

The build-up circuitry can extend from, contact and cover the closed end and the adhesive in the first vertical direction. Furthermore, the build-up circuitry can include one or more interconnect pads that are defined from selected portions of outer conductive traces and electrically connected to the electrical pad or the conductive vias exposed from the cavity in the second vertical direction and extend from an insulating layer in the first vertical direction and include an exposed contact surface that faces in the first vertical direction to provide an electrical contact for the next level assembly or another electronic device such as a semiconductor chip, a plastic package or another semiconductor assembly.

The interconnect substrate can extend from, contact and cover the dielectric layer in the first vertical direction. Likewise, the interconnect substrate can include one or more interconnect pads that are defined from selected portions of outer circuitry and electrically connected to inner circuitry through conductive vias and extend from an insulating layer in the first vertical direction and include an exposed contact surface that faces in the first vertical direction to provide an electrical contact for the next level assembly or another electronic device such as a semiconductor chip, a plastic package or another semiconductor assembly.

The cavity substrate provided by the present invention can further include: a terminal that extends from the stiffener in the second vertical direction and is spaced from the build-up circuitry by the stiffener and the adhesive or is spaced from the interconnect substrate by the stiffener, the adhesive and the dielectric layer; and a plated through-hole that extends through the adhesive and the stiffener to provide an electrical connection between the build-up circuitry and the terminal or the interconnect substrate and the terminal. The terminal can include an exposed contact surface that faces in the second vertical direction as another electrical contact for the next level assembly or another electronic device. As a result, the cavity substrate includes electrical contacts that are electrically connected to one another and located on opposite surfaces that face in opposite vertical directions so that the cavity substrate is stackable.

The present invention also provides a semiconductor assembly in which a semiconductor device can extend into the built-in cavity and be electrically connected to the electrical contacts (e.g. the electrical pad, the conductive vias, or the exposed portion of the circuitry layer) exposed from the cavity using a wide variety of connection media including gold or solder bumps or bonding wires. Optionally, an under-fill can be dispensed within the cavity and a heat sink may be attached on the semiconductor device to enhance thermal performance.

Moreover, the present invention further provides a three-dimensional stacking structure where plural stackable semiconductor assemblies each with a semiconductor device embedded in the cavity are stacked using a wide variety of connection media. For instance, the assemblies can be face-to-back vertically stacked using solder balls between the terminal of the bottom assembly and the interconnect pad of the top assembly.

The semiconductor device can be a packaged or unpackaged semiconductor chip. For instance, the semiconductor device can be a land grid array (LGA) package or wafer level package (WLP) that includes a semiconductor chip or an assembly with chips on an interposer. Alternatively, the semiconductor device can be a semiconductor chip.

The assembly can be a first-level or second-level single-chip or multi-chip device. For instance, the assembly can be a first-level package that contains a single chip or multiple chips. Alternatively, the assembly can be a second-level module that contains a single package or multiple packages, and each package can contain a single chip or multiple chips.

Unless specific descriptions or using the term “then” between steps or steps necessarily occurring in a certain order, the sequence of the above-mentioned steps is not limited to that set forth above and may be changed or reordered according to desired design.

The present invention has numerous advantages. The stiffener provides a mechanical support for the coreless build-up circuitry or the interconnect substrate. The metal block formed by removing a selected portion of the sacrificial carrier can only be separated from the dielectric layer by etching to create a cavity area for device placement and thus ensure a high manufacturing yield without un-predictable peeling or delamination concern. Furthermore, vast options of the built-in stiffener ranging from low coefficient of thermal expansion (CTE) materials like ceramics, to high thermal conductive materials like metal plate, to low cost materials like glass-fiber epoxy provide diversified solutions for various packaging designs. As a result, a semiconductor device can be mounted into the cavity without special alignment tool to achieve low profile and small form-factor requirements. The electrical connection between the semiconductor device and the build-up circuitry or between the semiconductor device and the interconnect substrate can be successfully established through the electrical contacts at the cavity without the troublesome matter that the lamination-induced displacement and warping which often cause the failure of semiconductor package. The plated through-hole can provide vertical signal routing between the build-up circuitry and the terminal or between the interconnect substrate and the terminal, thereby providing the cavity substrate with stacking capability.

These and other features and advantages of the present invention will be further described and more readily apparent from a review of the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1A-1J are cross-sectional views showing a method of making a cavity substrate that includes electrical pads exposed from a cavity, a stiffener, an adhesive, a build-up circuitry in electrical connection with the electrical pads, terminals and plated through-holes that provide an electrical connection between the build-up circuitry and the terminals in accordance with an embodiment of the present invention;

FIG. 1K is a cross-sectional view showing a three dimensional assembly with semiconductor devices attached onto an interposer packaged in a cavity substrate at one side and another semiconductor device attached onto the cavity substrate at the other side in accordance with an embodiment of the present invention;

FIG. 1L is a cross-sectional view showing a three dimensional stacking structure that includes stackable semiconductor assemblies vertically stacked in a face-to-back manner in accordance with an embodiment of the present invention;

FIGS. 2A-2G are cross-sectional views showing a method of making a cavity substrate that includes a stiffener, an adhesive, a build-up circuitry that includes conductive vias exposed from a cavity, terminals and plated through-holes that provide an electrical connection between the build-up circuitry and the terminals in accordance with another embodiment of the present invention;

FIGS. 3A-3H are cross-sectional views showing a method of making a cavity substrate that includes a stiffener, an adhesive, a dielectric layer, an interconnect substrate, conductive vias electrically connected to the interconnect substrate and exposed from a cavity, terminals and a plated through-hole that provides an electrical connection between the interconnect substrate and the terminals in accordance with yet another embodiment of the present invention;

FIGS. 4A-4F are cross-sectional views showing a method of making a three-dimensional semiconductor assembly that includes a stiffener, an adhesive, electrical pads, a semiconductor device, dual build-up circuitries and plated through-holes in accordance with an embodiment of the present invention; and

FIGS. 5A-5F are cross-sectional views showing a method of making a three-dimensional semiconductor assembly that includes a stiffener, an adhesive, a dielectric layer, a semiconductor device, an interconnect substrate, dual build-up circuitries and plated through-holes in accordance with another embodiment of the present invention.

### DETAILED DESCRIPTION OF THE PREFERRED EMBODIMENT

### Embodiment 1

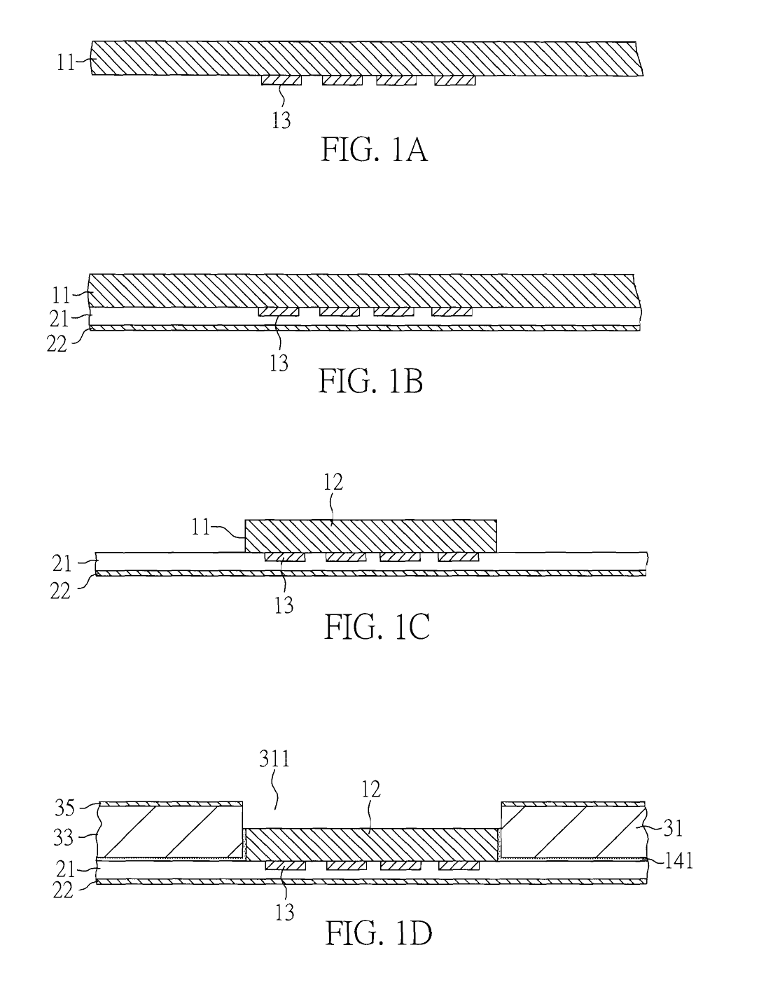

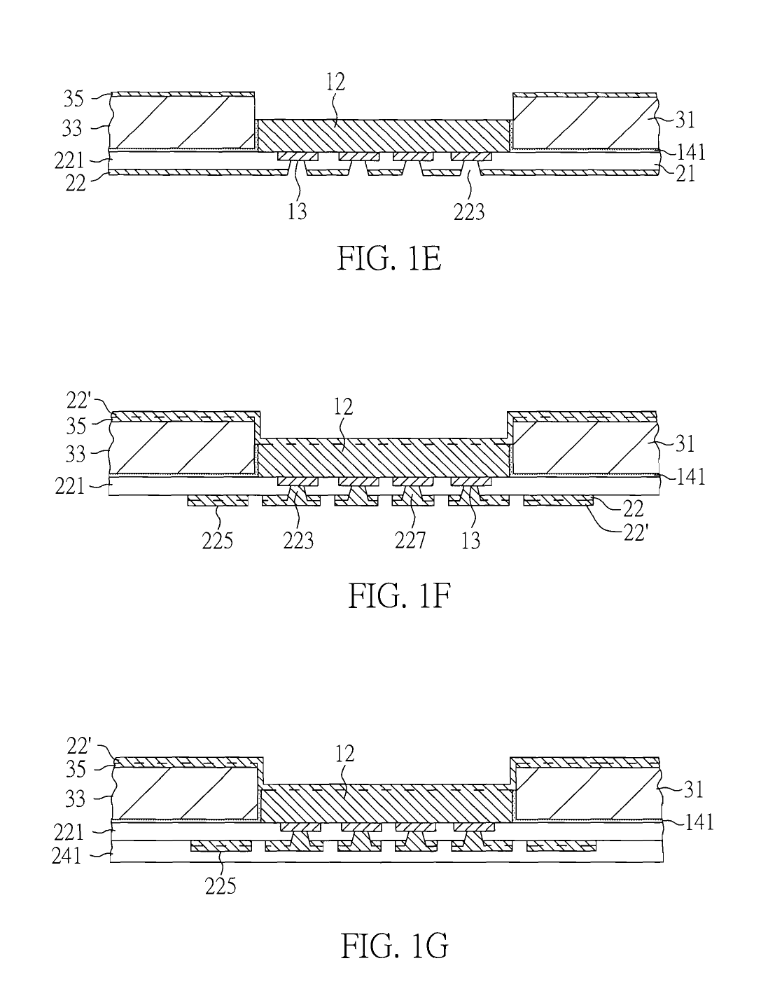

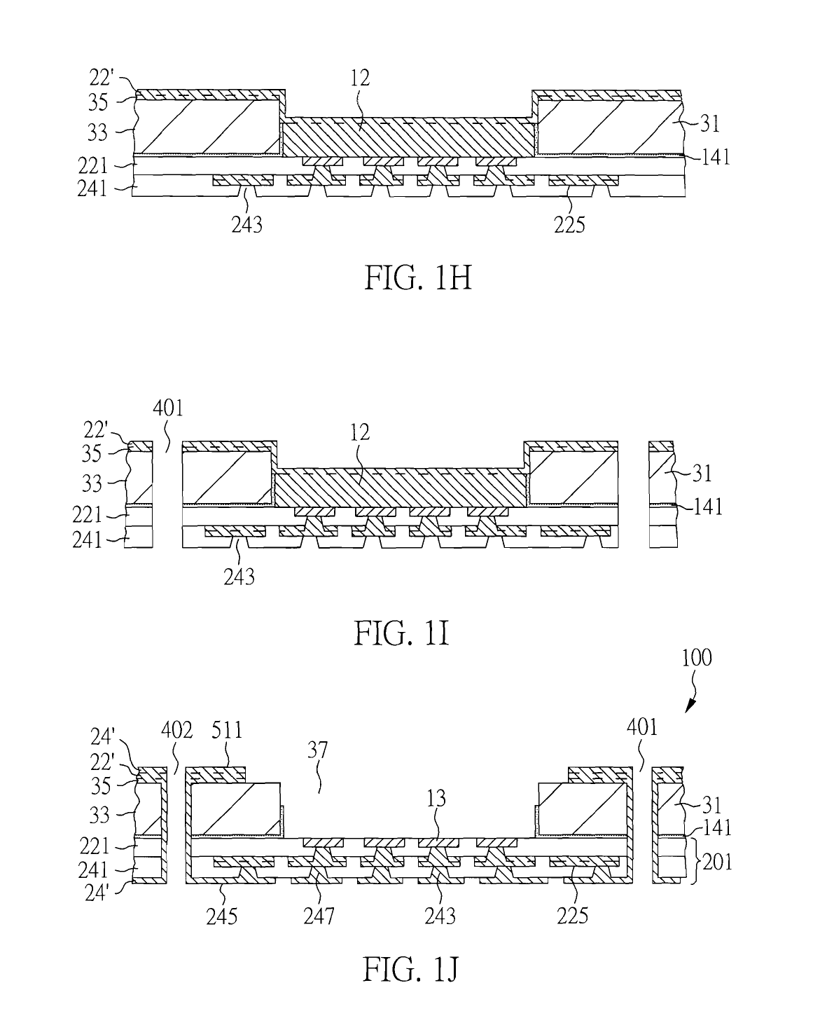

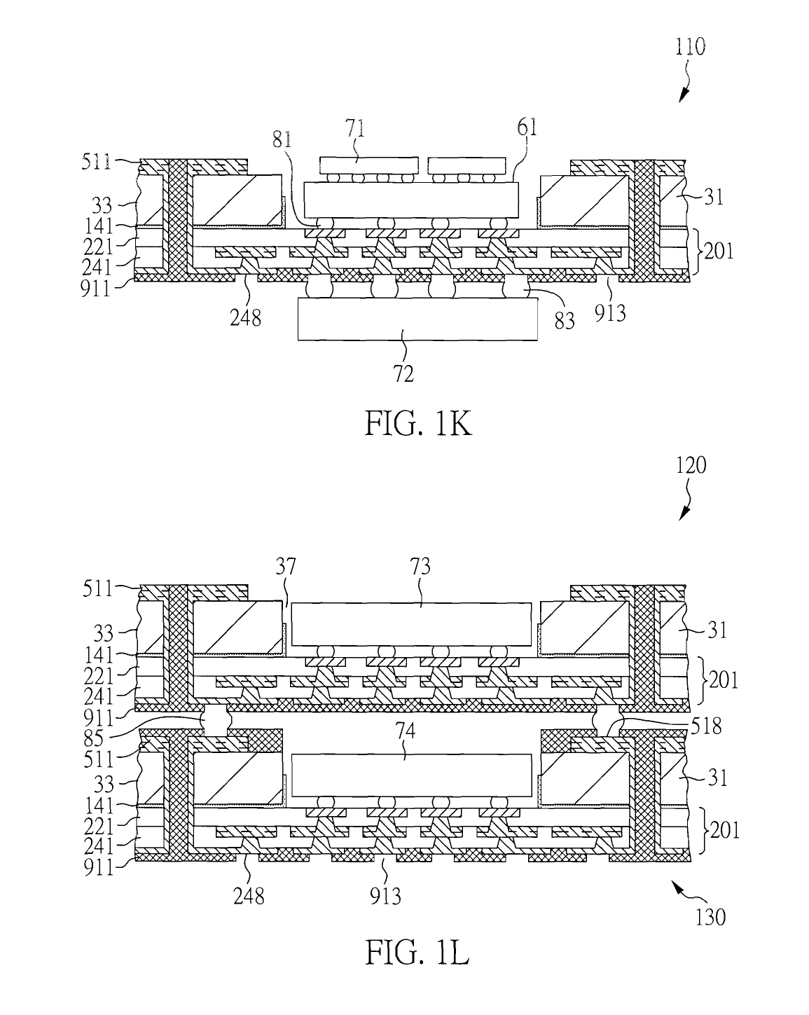

FIGS. 1A-1J are cross-sectional views showing a method of making a cavity substrate that includes electrical pads exposed from a cavity, a stiffener, an adhesive, a build-up circuitry in electrical connection with the electrical pads, terminals and plated through-holes that provide an electrical connection between the build-up circuitry and the terminals in accordance with one embodiment of the present invention.

FIG. 1A is a cross-sectional view of the structure with electrical pads 13 on sacrificial carrier 11. Sacrificial carrier 11 typically is made of copper, but other materials such as aluminum, alloy 42, iron, nickel, silver, gold, tin, combinations thereof, and alloys thereof are also doable. In consideration of process and cost, the thickness of sacrificial carrier 11 preferably ranges from 125 to 500 microns. Electrical pads 13 extend from sacrificial carrier 11 in the downward direction and are covered by sacrificial carrier 11 in the upward direction. Electrical pads 13 can be various stable materials against etching during removal of sacrificial carrier 11 and pattern deposited by numerous techniques including electroplating, electroless plating, evaporating, sputtering and their combinations or thin-film deposited followed by etching. In this embodiment, sacrificial carrier 11 is illustrated as a copper sheet with a thickness of 200 microns, and electrical pads 13 are illustrated as gold pads.

FIG. 1B is a cross-sectional view of the structure with dielectric layer 21 sandwiched between sacrificial carrier 11 and metal layer 22 and between electrical pads 13 and metal layer 22. Dielectric layer 21, such as epoxy resin, glass-epoxy, polyimide and the like, may be deposited by numerous techniques including film lamination, roll coating, spin coating and spray-on deposition. Furthermore, dielectric layer 21 may be treated by plasma etching or coated with an adhesion promoter (not shown) to promote adhesion. In this illustration, dielectric layer 21 has a thickness of 50 microns and contacts and provides secure robust mechanical bonds between sacrificial carrier 11 and metal layer 22 and between electrical pads 13 and metal layer 22. Metal layer 22 is illustrated as a copper layer with a thickness of about 35 microns.

FIG. 1C is a cross-sectional view of the structure with metal block 12 defined by removing a selected portion of sacrificial carrier 11 using photolithography and wet etching. Metal block 12 covers electrical pads 13 in the upward direction, and partial dielectric layer 21 is exposed from the upward direction.

FIG. 1D is a cross-sectional view of the structure with stiffener 31 mounted on dielectric layer 21 using adhesive 141. Metal block 12 is aligned with and inserted into aperture 311 of stiffener 31 and stiffener 31 is mounted on dielectric layer 21 using adhesive 141. Adhesive 141 contacts and is sandwiched between stiffener 31 and dielectric layer 21, and is further forced into a gap between metal block 12 and stiffener 31. In this illustration, stiffener 31 includes substrate 33 and conductive layer 35. For instance, substrate 33 is a glass-epoxy material with a thickness of 950 microns and conductive layer 35 that contacts and extends above and is laminated to substrate 33 is an unpatterned copper sheet with a thickness of 30 microns. Stiffener 31 can also be an electrical interconnect such as a multi-layer printed circuit board or a multi-layer ceramic board. Accordingly, stiffener 31 can include embedded circuitry. Aperture 311 is formed by punching through substrate 33 and conductive layer 35 and can be formed with other techniques such as laser cutting with or without wet etching.

FIG. 1E is a cross-sectional view of the structure showing first via openings 223 formed through metal layer 22 and dielectric layer 21 to expose electrical pads 13. First via openings 223 may be formed by numerous techniques including laser drilling, plasma etching and photolithography. Laser drilling can be enhanced by a pulsed laser. Alternatively, a scanning laser beam with a metal mask can be used. For instance, metal can be etched first to create a metal window followed by laser. First via openings 223 typically have a diameter of 50 microns, and dielectric layer 21 is considered first insulating layer 221 of build-up circuitry.

Referring now to FIG. 1F, first conductive traces 225 are formed on first insulating layer 221. First conductive traces 225 extend from first insulating layer 221 in the downward direction, extend laterally on first insulating layer 221 and extend into first via openings 223 in the upward direction to form first conductive vias 227 in electrical contact with electrical pads 13. In this illustration, first conductive traces 225 are formed by depositing first plated layer 22′ on metal layer 22 and into first via openings 223, and then patterning metal layer 22 and first plated layer 22′ thereon. Alternatively, in some embodiments which laminate only blanket dielectric film onto sacrificial carrier 11 and electrical pads 13, the first insulating layer 221 can be directly metallized to form first conductive traces 225 after forming first via openings 223.

First conductive traces 225 can provide horizontal signal routing in both the X and Y directions and vertical (top to bottom) routing through first via openings 223 and serve as electrical connections for electrical pads 13.

First plated layer 22′ can be deposited by numerous techniques including electroplating, electroless plating, evaporating, sputtering, and their combinations as a single layer or multiple layers. For instance, first plated layer 22′ is deposited by first dipping the structure in an activator solution to render the insulating layer catalytic to electroless copper, and then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, metal layer 22 and first plated layer 22′ can be patterned to form first conductive traces 225 by numerous techniques including wet etching, electro-chemical etching, laser-assist etching, and their combinations with an etch mask (not shown) thereon that defines first conductive traces 225.

Metal layer 22 and first plated layer 22′ thereon are shown as a single layer for convenience of illustration. The boundary (shown in phantom) between the metal layers may be difficult or impossible to detect since copper is plated on copper. However, the boundary between first plated layer 22′ and first insulating layer 221 is clear.

Also shown in FIG. 1F is first plated layer 22′ further deposited on metal block 12 and conductive layer 35 in the upward direction. First plated layer 22′ at the lateral top surface is an unpatterned copper layer that contacts and covers metal block 12 and conductive layer 35 in the upward direction. Metal block 12, conductive layer 35 and first plated layer 22′ are shown as a single layer for convenience of illustration. The boundary (shown in phantom) between metal block 12 and first plated layer 22′ and between conductive layer 35 and first plated layer 22′ may be difficult or impossible to detect since copper is plated on copper.

FIG. 1G is a cross-sectional view of the structure provided with second insulating layer 241 disposed on first conductive traces 225 and first insulating layer 221. Like first insulating layer 221, second insulating layer 241 can be epoxy resin, glass-epoxy, polyimide and the like deposited by numerous techniques including film lamination, spin coating, roll coating, and spray-on deposition and has a thickness of 50 microns. Preferably, first insulating layer 221 and second insulating layer 241 are the same material with the same thickness formed in the same manner.

FIG. 1H is a cross-sectional view of the structure showing second via openings 243 formed through second insulating layer 241 to expose selected portions of first conductive traces 225. Like first via openings 223, second via openings 243 can be formed by numerous techniques including laser drilling, plasma etching and photolithography and have a diameter of 50 microns. Preferably, first via openings 223 and second via openings 243 are formed in the same manner and have the same size.

FIG. 1I is a cross-sectional view of the structure with through-holes 401. Through-holes 401 extend through second insulating layer 241, first insulating layer 221, adhesive 141, stiffener 31 and first plated layer 22′ in the vertical direction. Through-holes 401 are formed by mechanical drilling and can be formed by other techniques such as laser drilling and plasma etching with or without wet etching.

Referring now to FIG. 1J, second conductive traces 245 are formed on second insulating layer 241 by depositing second plated layer 24′ on second insulating layer 241 and into second via openings 243 and then patterning second plated layer 24′. Second conductive traces 245 extend from second insulating layer 241 in the downward direction, extend laterally on second insulating layer 241 and extend into second via openings 243 in the upward direction to form second conductive vias 247 in electrical contact with first conductive traces 225. Second plated layer 24′ can be deposited by numerous techniques including electrolytic plating, electroless plating, sputtering, and their combination and then patterned by numerous techniques including wet etching, electro-chemical etching, laser-assist etching, and their combinations with an etch mask (not shown) thereon that defines second conductive traces 245. Preferably, first conductive traces 225 and second conductive traces 245 are the same material with the same thickness formed in the same manner.

Also shown in FIG. 1J is second plated layer 24′ further deposited on first plated layer 22′ at the lateral top surface and deposited as a connecting layer in through-holes 401 to provide plated through-holes 402. In this illustration, second plated layer 24′ in through-holes 401 is a hollow tube that covers the sidewall of through-holes 401 in lateral directions and extends vertically to electrically connect conductive layer 35 as well as first and second plated layer 22′, 24′ to second conductive traces 245. Alternatively, second plated layer 24′ can fill through-holes 401 in which case plated through-holes 402 are metal posts. Conductive layer 35, first plated layer 22′ and second plated layer 24′ are shown as a single layer for convenience of illustration. The boundary (shown in phantom) between the metal layers may be difficult or impossible to detect since copper is plated on copper. However, the boundaries between second plated layer 24′ and substrate 33, between second plated layer 24′ and adhesive 141, between second plated layer 24′ and first insulating layer 221 and between second plated layer 24′ and second insulating layer 241 are clear. After metal deposition, metal block 12 and selected portions of conductive layer 35 as well as first and second plated layers 22′, 24′ thereon are removed to define cavity 37 and terminals 511 by numerous techniques including wet chemical etching using acidic solution (e.g., Ferric Chloride, Copper Sulfate solutions), or alkaline solution (e.g., Ammonia solution), electro-chemical etching, or mechanical process such as a drill or end mill followed by chemical etching.

Accordingly, as shown in FIG. 1J, cavity substrate 100 is accomplished and includes stiffener 31, adhesive 141, electrical pads 13, build-up circuitry 201, terminals 511 and plated through-holes 402. In this illustration, build-up circuitry 201 includes first insulating layer 221, first conductive traces 225, second insulating layer 241 and second conductive traces 245 and is electrically connected to terminals 511 through plated through-holes 402. However, in some embodiments, terminal 511 and plated through-hole 402 may be omitted according to desired design, and build-up circuitry 201 may include additional interconnect layers (i.e. a third insulating layer with third via openings, third conductive traces and so on) if desired. Furthermore, cavity substrate 100 may include multiple cavities 37 defined by multiple metal blocks 12.

Stiffener 31 is bonded to build-up circuitry 201 through adhesive 141 and can provide mechanical support for build-up circuitry 201. Cavity 37 is laterally covered and surrounded by stiffener 31, and has a closed end in the downward direction and an open end in the upward direction.

Electrical pads 13 extend from the closed end of cavity 37 in the downward direction and are coplanar with first insulating layer 221 and exposed from cavity 37 in the upward direction. Electrical pads 13 can serve as electrical contacts for a semiconductor device embedded in cavity 37 and provide an electrical connection between the semiconductor device and build-up circuitry 201.

Terminal 511 extends from substrate 33 in the upward direction, is spaced from build-up circuitry 201 and is adjacent to and integral with plated through-hole 402. Terminal 511 has a combined thickness of conductive layer 35, first plated layer 22′ and second plated layer 24′, and can be used for grounding or/and supporting a heat sink attached on an embedded semiconductor device in cavity 37 or serve as an electrical contact for another semiconductor device or assembly.

Plated through-hole 402 is spaced from first conductive traces 225 and extends vertically from terminal 511 to second conductive traces 245 through second insulating layer 241, first insulating layer 221, adhesive 141 and substrate 33 in an electrically conductive path between terminal 511 and second conductive traces 245. Thus, plated through-hole 402 extends from terminal 511 to the outer conductive layer of build-up circuitry 201 and is spaced from the inner conductive layer of build-up circuitry 201.

Cavity substrate 100 can accommodate multiple semiconductor devices rather than one with a single cavity or multiple cavities. Thus, multiple semiconductor devices can be mounted into a single cavity or separate semiconductor devices can be mounted into separate cavities. Accordingly, additional electrical pads 13 may be provided and build-up circuitry 201 may include additional conductive traces for additional devices.

FIG. 1K is a cross-sectional view showing three dimensional assembly 110. Multiple chips 71 are attached on interposer 61 which is electrically coupled to build-up circuitry 201 via solder bumps 81 on electrical pads 13 located in cavity 37. Besides, another chip 72 is aligned with the placement location of interposer 61 and can be electrically coupled to build-up circuitry 201 via solder bumps 83 on interconnect pads 248. Interconnect pads 248 exposed from opening 913 of solder mask material 911 can accommodate a conductive joint, such as solder bump, solder ball, pin, and the like, for electrical communication and mechanical attachment with external components or a PCB. The solder mask openings 913 may be formed by numerous techniques including photolithography, laser drilling and plasma etching.

FIG. 1L is a cross-sectional view showing a three dimensional stacking structure. Top and bottom assemblies 120, 130 each respectively with chip 73, 74 in cavity 37 are stacked via solder balls 85 between bottom interconnect pads 248 of top assembly 120 and top interconnect pads 518 of bottom assembly 130. In this illustration, two assemblies are stacked. However, more assemblies may be stacked if desired.

### Embodiment 2

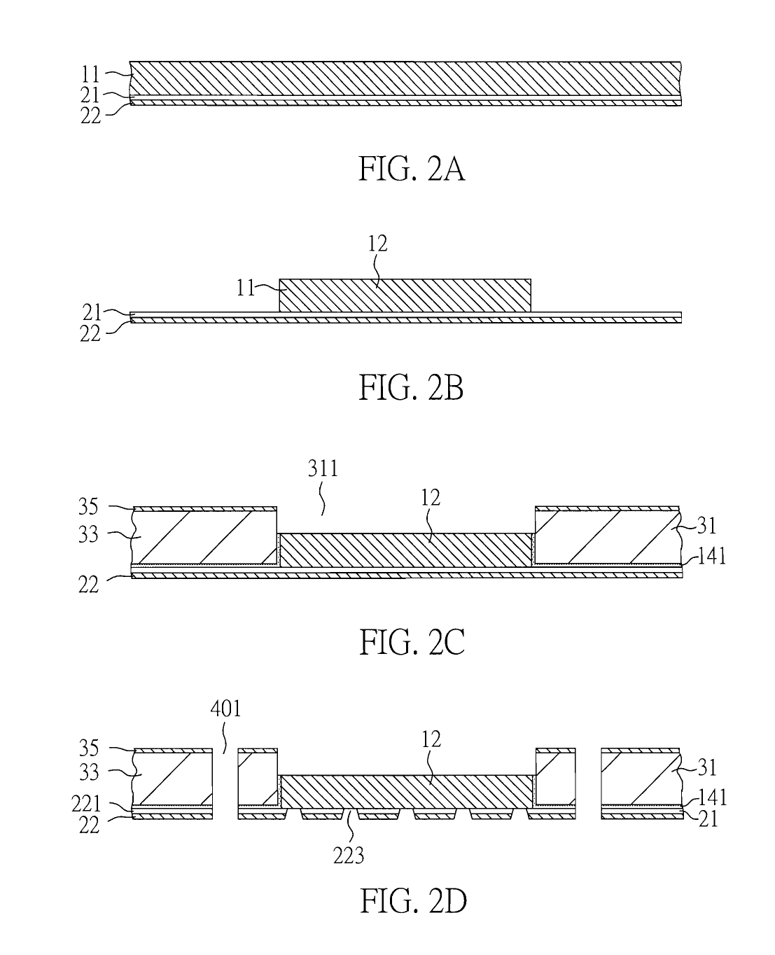

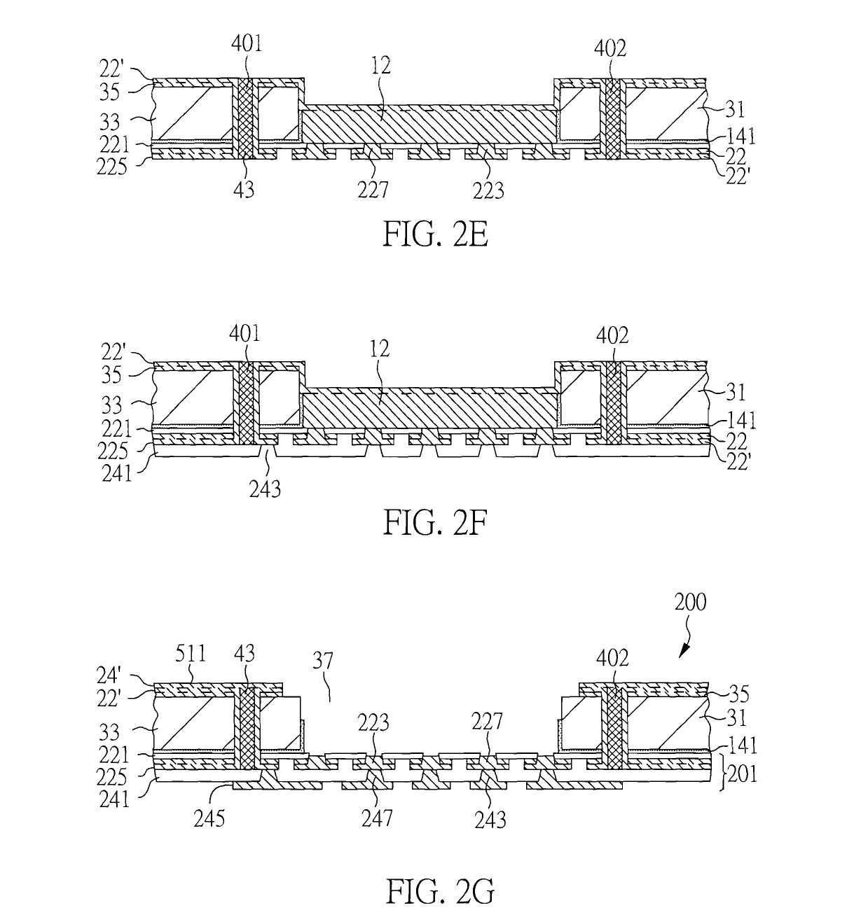

FIGS. 2A-2G are cross-sectional views showing a method of making a cavity substrate that includes a stiffener, an adhesive, a build-up circuitry that includes conductive vias exposed from a cavity, terminals and plated through-holes that provide an electrical connection between the build-up circuitry and the terminals in accordance with another embodiment of the present invention.

For purposes of brevity, any description in above Embodiment is incorporated herein insofar as the same is applicable, and the same description need not be repeated.

FIG. 2A is a cross-sectional view of the structure with sacrificial carrier 11 laminated with metal layer 22 using dielectric layer 21 between sacrificial carrier 11 and metal layer 22. Sacrificial carrier 11 can be various metals such as copper, aluminum, alloy 42, iron, nickel, silver, gold, tin, combinations thereof, and alloys thereof. In order to prevent conductive vias subsequently formed in contact with sacrificial carrier 11 from being etched during removal of sacrificial carrier 11, sacrificial carrier 11 may be made of a material such as tin or stainless steel that can be removed using an etching solution inactive to the conductive vias. Alternatively, sacrificial carrier 11 may include a barrier layer thereon that can protect the conductive vias from etching during removal of sacrificial carrier 11. However, even though sacrificial carrier 11 is made of the same material as the conductive vias, the outcome of conductive vias being slightly etched during removal of sacrificial carrier 11 is also acceptable and even better. Thereby, in this embodiment, sacrificial carrier 11 is illustrated as a copper sheet with a thickness of 200 microns.

Dielectric layer 21 typically is made of epoxy resin, glass-epoxy, polyimide and the like and has a thickness of 50 microns. Metal layer 22 is illustrated as a copper layer with a thickness of about 35 microns and may be omitted in some embodiments.

FIG. 2B is a cross-sectional view of the structure with metal block 12 defined by removing a selected portion of sacrificial carrier 11 using photolithography and wet etching. Metal block 12 covers a predetermined area for creating a cavity, and partial dielectric layer 21 is exposed from the upward direction.

FIG. 2C is a cross-sectional view of the structure with stiffener 31 mounted on dielectric layer 21 using adhesive 141. Metal block 12 is aligned with and inserted into aperture 311 of stiffener 31, and stiffener 31 is mounted on dielectric layer 21 using adhesive 141 with substrate 33 facing dielectric layer 21. Adhesive 141 contacts and is sandwiched between stiffener 31 and dielectric layer 21, and is further forced into a gap between metal block 12 and stiffener 31.

FIG. 2D is a cross-sectional view of the structure provided with first via openings 223 and through-holes 401. First via openings 223 are aligned with metal block 12 and extend through metal layer 22 and dielectric layer 21 that is considered first insulating layer 221 of build-up circuitry. Through-holes 401 extend through stiffener 31, adhesive 141, dielectric layer 21 and metal layer 22 in the vertical direction.

FIG. 2E is a cross-sectional view of the structure showing first conductive traces 225 formed on first insulating layer 221 by depositing and patterning metal. First conductive traces 225 are formed by depositing first plated layer 22′ on metal layer 22 and into first via openings 223 and then patterning metal layer 22 and first plated layer 22′ thereon. First plated layer 22′ covers and extends from metal layer 22 in the downward direction and extends into first via openings 223 in the upward direction to form first conductive vias 227 in contact with metal block 12. First plated layer 22′ also covers metal block 12 and conductive layer 35 in the upward direction and is deposited as a connecting layer on the inner sidewall of through-holes 401 to provide plated through-holes 402. Plated through-holes 402 extend vertically to electrically connect conductive layer 35 as well as first plated layer 22′ thereon to first conductive traces 225. Also shown in FIG. 2E is insulative filler 43 in through-hole 401 that fills the remaining space in through-holes 401. The boundary (shown in phantom) between the metal layers may be difficult or impossible to detect since copper is plated on copper. However, the boundaries between first plated layer 22′ and substrate 33, between first plated layer 22′ and adhesive 141 and between first plated layer 22′ and first insulating layer 221 are clear.

FIG. 2F is a cross-sectional view of the structure showing second insulating layer 241 with second via openings 243. Second insulating layer 241 is disposed on first conductive traces 225 and first insulating layer 221, and second via openings 243 extend through second insulating layer 241 and expose selected portions of first conductive traces 225.

FIG. 2G is the cross-sectional view of the structure showing second conductive traces 245 formed on second insulating layer 241 by depositing second plated layer 24′ on second insulating layer 241 and into second via openings 243 and then patterning second plated layer 24′. Second conductive traces 245 extend from second insulating layer 241 in the downward direction, extend laterally on second insulating layer 241 and extend into second via openings 243 in the upward direction to form second conductive vias 247 in electrical contact with first conductive traces 225. Also shown in FIG. 2G is second plated layer 24′ further deposited on first plated layer 22′ and insulative filler 43 at the lateral top surface. The boundary (shown in phantom) between the metal layers may be difficult or impossible to detect since copper is plated on copper. However, the boundaries between second plated layer 24′ and insulative filler 43 and between second plated layer 24′ and second insulating layer 241 are clear. After metal deposition, metal block 12 and selected portions of conductive layer 35 as well as first and second plated layers 22′, 24′ thereon are removed to expose first conductive vias 227 from cavity 37 and define terminals 511. In this illustration, as metal block 12 and first conductive vias 227 are made of the same material, first conductive vias 227 are slightly etching during removal of metal block 12. Thereby, at the closed end of cavity 37, first conductive vias 227 are lower than first insulating layer 221.

Accordingly, as shown in FIG. 2G, cavity substrate 200 is accomplished and includes stiffener 31, adhesive 141, build-up circuitry 201, terminals 511 and plated through-holes 402. In this illustration, build-up circuitry 201 includes first insulating layer 221, first conductive traces 225, second insulating layer 241 and second conductive traces 245. First conductive traces 225 extend into first via openings 223 of first insulating layer 221 in the upward direction to form first conductive vias 227 that are exposed from cavity 37 in the upward direction. First conductive vias 227 of first conductive traces 225 can serve as electrical contacts for a semiconductor device embedded in cavity 37 and provide an electrical connection between the semiconductor device and build-up circuitry 201. Terminal 511 extends from substrate 33 in the upward direction and is spaced from build-up circuitry 201 by stiffener 31 and adhesive 141, and is adjacent to and is electrically connected to plated through-holes 402. Plated through-hole 402 is spaced from second conductive traces 245 and extends from terminals 511 to first conductive traces 225 through substrate 33, adhesive 141 and first insulating layer 221 in an electrically conductive path between build-up circuitry 201 and terminals 511. Thus, plated through-hole 402 extends from terminal 511 to the inner conductive layer of build-up circuitry 201 and is spaced from the outer conductive layer of build-up circuitry 201.

### Embodiment 3

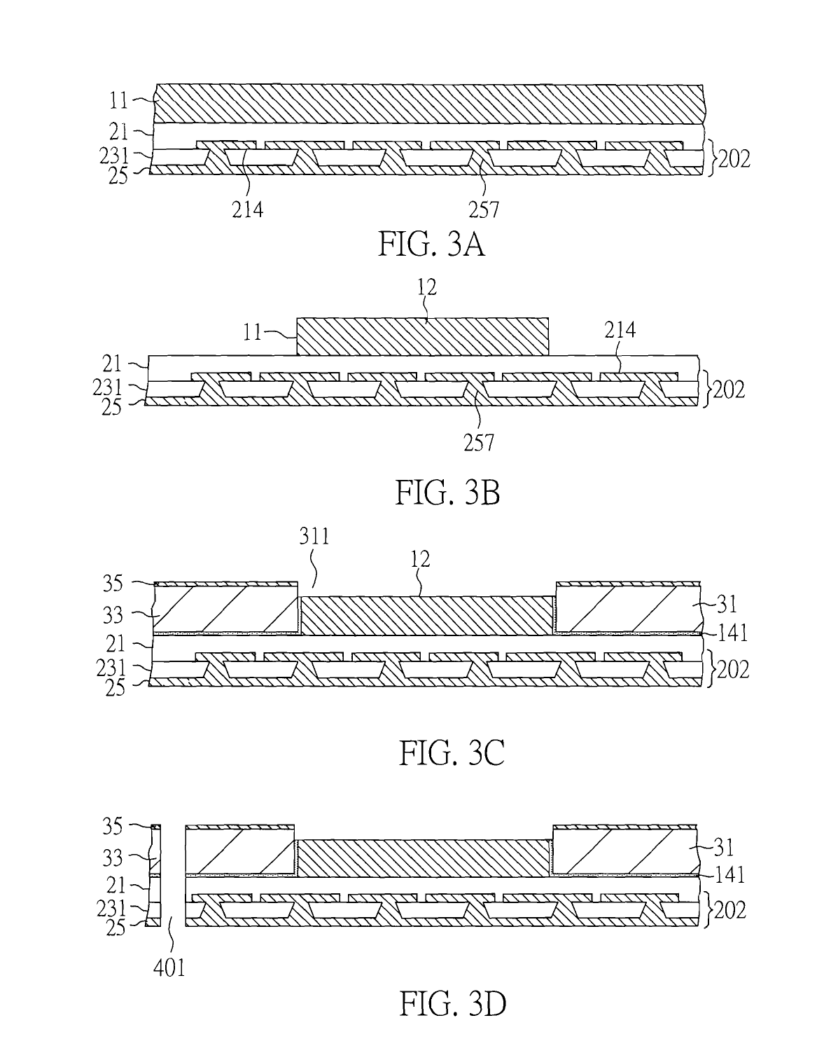

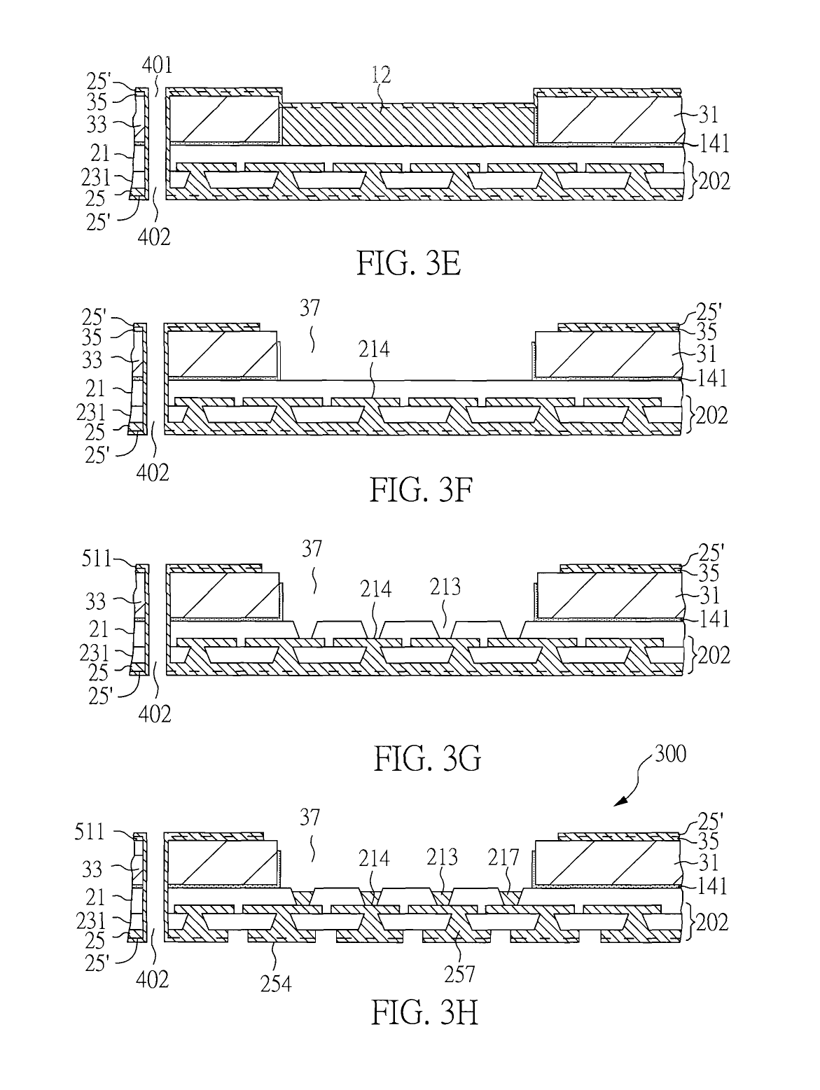

FIGS. 3A-3H are cross-sectional views showing a method of making a cavity substrate that includes a stiffener, an adhesive, a dielectric layer, an interconnect substrate, conductive vias electrically connected to the interconnect substrate and exposed from a cavity, terminals and a plated through-hole that provides an electrical connection between the interconnect substrate and the terminals in accordance with yet another embodiment of the present invention.

For purposes of brevity, any description in above Embodiments is incorporated herein insofar as the same is applicable, and the same description need not be repeated.

FIG. 3A is a cross-sectional view of the structure with sacrificial carrier 11 laminated onto interconnect substrate 202 using dielectric layer 21, such as epoxy resin, glass-epoxy, polyimide and the like with a thickness of 50 microns. Interconnect substrate 202 includes first circuitry layer 214, first insulating layer 231, metal layer 25 and first conductive vias 257, and is laminated with sacrificial carrier 11 using dielectric layer 21 in contact with sacrificial carrier 11, first circuitry layer 214 and first insulating layer 231. Like dielectric layer 21, first insulating layer 231 can be epoxy resin, glass-epoxy, polyimide and the like with a thickness of 50 microns and is sandwiched between first circuitry layer 214 and metal layer 25. Preferably, dielectric layer 21 and first insulating layer 231 are the same material with the same thickness. First circuitry layer 214 is illustrated as a patterned copper layer, and contacts and is covered by dielectric layer 21 in the upward direction. Metal layer 25 is illustrated as an un-patterned copper layer and covers first insulating layer 231 in the downward direction. First conductive vias 257 are illustrated as copper posts with a diameter of 50 microns and extend through first insulating layer 231 and contact first circuitry layer 214 and metal layer 25 to provide an electrical connection between first circuitry layer 214 and metal layer 25.

FIG. 3B is a cross-sectional view of the structure with metal block 12 defined by removing a selected portion of sacrificial carrier 11 using photolithography and wet etching. Metal block 12 covers a predetermined area for creating a cavity, and partial dielectric layer 21 is exposed from the upward direction.

FIG. 3C is a cross-sectional view of the structure with stiffener 31 mounted on dielectric layer 21 using adhesive 141. Metal block 12 is aligned with and inserted into aperture 311 of stiffener 31, and stiffener 31 is mounted on dielectric layer 21 using adhesive 141 with substrate 33 facing dielectric layer 21. Adhesive 141 contacts and is sandwiched between stiffener 31 and dielectric layer 21, and is further forced into a gap between metal block 12 and stiffener 31.

FIG. 3D is a cross-sectional view of the structure provided with through-hole 401. Through-hole 401 extends through stiffener 31, adhesive 141, dielectric layer 21, first insulating layer 231 and metal layer 25 in the vertical direction.

Referring now to FIG. 3E, plated layer 25′ is deposited on lateral top and bottom surfaces of the structure and further deposited as a connecting layer on an inner sidewall of through-hole 401 to provide plated through-hole 402. Plated through-hole 402 extends vertically to electrically connect conductive layer 35 and plated layer 25′ thereon to metal layer 25 and plated layer 25′ thereon. The boundary (shown in phantom) between the metal layers may be difficult or impossible to detect since copper is plated on copper. However, the boundaries between the metal layers and substrate 33, adhesive 141, dielectric layer 21 and first insulating layer 231 are clear.

FIG. 3F is a cross-sectional view of the structure with dielectric layer 21 exposed from cavity 37. Cavity 37 is defined by removing metal block 12 as well as plated layer 25′ thereon, thereby exposing dielectric layer 21 from cavity 37. Simultaneously, selected portions of conductive layer 35 as well as plated layer 25′ thereon are removed to form terminal 511 with an etch mask (not shown) thereon that define terminal 511. Terminal 511 has a combined thickness of conductive layer 35 and plated layer 25′.

FIG. 3G is a cross-sectional view of the structure provided with via openings 213. Via openings 213 extend through dielectric layer 21 to expose selected portions of first circuitry layer 214 of interconnect substrate 202 from cavity 37.

FIG. 3H is a cross-sectional view of cavity substrate 300 with conductive vias 217 in via openings 213 of dielectric layer 21. Conductive vias 217 can be deposited by numerous techniques including electroplating, electroless plating, evaporating, sputtering, and their combinations as a single layer or multiple layers. Conductive vias 217 extend from first circuitry layer 214 of interconnect substrate 202 in the upward direction and are lower than dielectric layer 21 in the upward direction. After depositing conductive vias 217, metal layer 25 and plated layer 25′ thereon are patterned with an etch mask (not shown) thereon that defines second circuitry layer 254.

At this stage, as shown in FIG. 3H, interconnect substrate 202 includes first circuitry layer 214, first insulating layer 231, first conductive vias 257 and second circuitry layer 254. First circuitry layer 214 extends from first insulating layer 231 in the upward direction and extends laterally on first insulating layer 231. Second circuitry layer 254 extends from first insulating layer 231 in the downward direction and extends laterally on first insulating layer 231. First circuitry layer 214 and second circuitry layer 254 can be electrically connected to one another through first conductive vias 257 that extend through first insulating layer 231 and are adjacent to first circuitry layer 214 and second circuitry layer 254. Conductive vias 217 directly contacts first circuitry layer 214 and are exposed from cavity 37 in the upward direction and can serve as electrical contacts for a semiconductor device embedded in cavity 37 and provide an electrical connection between the semiconductor device and interconnect substrate 202. Plated through-hole 402 is spaced from first circuitry layer 214 and extends vertically from terminal 511 to second circuitry layer 254 through first insulating layer 231, dielectric layer 21, adhesive 141 and substrate 33 in an electrically conductive path between terminal 511 and second circuitry layer 254. Thus, plated through-hole 402 extends from terminal 511 to the outer conductive layer of interconnect substrate 202 and is spaced from the inner conductive layer of interconnect substrate 202.

Interconnect substrate 202 may include additional interconnect layers (i.e. a second insulating layer, second conductive vias, a third circuitry layer and so on), if desired.

Cavity substrate 300 can accommodate multiple semiconductor devices rather than one with a single cavity or multiple cavities. Thus, multiple semiconductor devices can be mounted into a single cavity or separate semiconductor devices can be mounted into separate cavities. Accordingly, interconnect substrate 202 may include additional conductive traces for additional devices.

### Embodiment 4

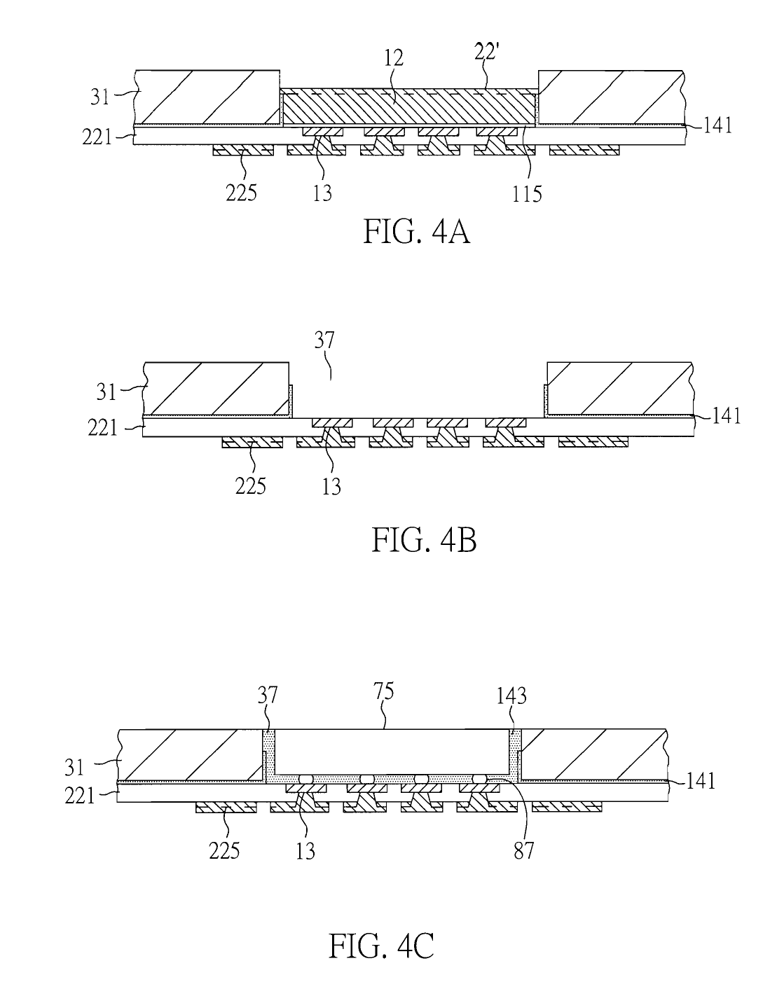

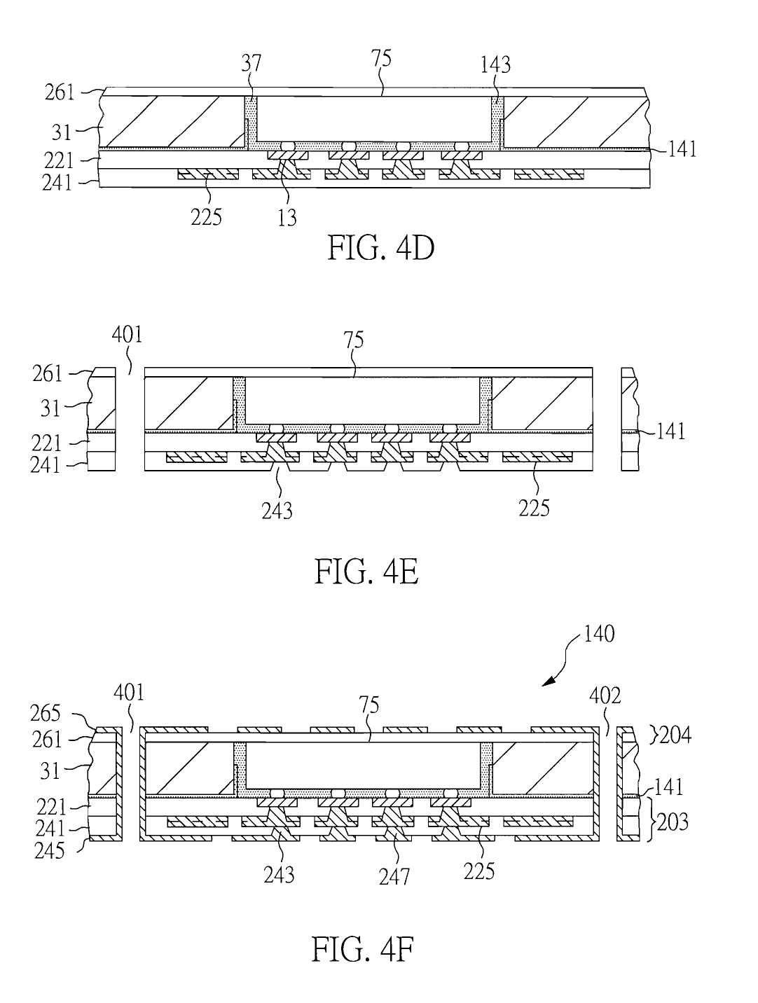

FIGS. 4A-4F are cross-sectional views showing a method of making a three-dimensional semiconductor assembly that includes a stiffener, electrical pads, an adhesive, a semiconductor device, dual build-up circuitries and plated through-holes in accordance with an embodiment of the present invention.

For purposes of brevity, any description in above Embodiments is incorporated herein insofar as the same is applicable, and the same description need not be repeated.

FIG. 4A is a cross-sectional view of the structure, which is manufactured by the steps shown in FIGS. 1A-1F. All elements illustrated in this embodiment are the same as those mentioned in Embodiment 1, except that metal block 12 further includes barrier layer 115 thereon and stiffener 31 includes no conductive layer thereon in this embodiment. Barrier layer 115 can be deposited by numerous techniques including electroplating, electroless plating, evaporating, sputtering and their combinations. Barrier layer 115 is illustrated as a tin layer but also can be made of other various barrier materials that can protect electrical pads 13 from etching during removal of copper blocks. Electrical pads 13 are deposited on barrier layer 115 and illustrated as copper pads. Other various materials that remain stable under removing barrier layer 115 are also doable for electrical pads 13.

FIG. 4B is a cross-sectional view of the structure with electrical pads 13 and partial first insulating layer 221 exposed from cavity 37. Metal block 12 and first plated layer 22′ thereon are removed to create cavity 37 from which electrical pads 13 and partial first insulating layer 221 are exposed in the upward direction.

FIG. 4C is a cross-sectional view of the structure with chip 75 mounted in cavity 37 and under-fill 143 dispensed within cavity 37. Chip 75 extends into cavity 37 and is electrically coupled to electrical pads 13 through solder bumps 87.

FIG. 4D is a cross-sectional view of the structure provided with second insulating layer 241 and third insulating layer 261 on bottom and top surfaces. Second insulating layer 241 covers first insulating layer 221 and first conductive traces 225 in the downward direction. Third insulating layer 261 covers chip 75, stiffener 31 and under-fill 143 in the upward direction. Preferably, second insulating layer 241 and third insulating layer 261 are the same material deposited simultaneously in the same manner and have the same thickness.

FIG. 4E is a cross-sectional view of the structure provided with through-holes 401 and second via openings 243. Through-holes 401 extend through third insulating layer 261, stiffener 31, adhesive 141, first insulating layer 221 and second insulating layer 241 in vertical directions. Second via openings 243 extend through second insulating layer 241 to expose selected portions of first conductive traces 225.

Referring now to FIG. 4F, second and third conductive traces 245, 265 are formed on second and third insulating layers 241, 261. Second conductive traces 245 extend from second insulating layer 241 in the downward direction, extend laterally on second insulating layer 241 and extend into second via openings 243 in the upward direction to form second conductive vias 247 in electrical contact with first conductive traces 225. Third conductive traces 265 extend from third insulating layer 261 in the upward direction and extend laterally on third insulating layer 261.

Also shown in FIG. 4F are plated through-holes 402 formed by depositing a connecting layer in through-hole 401. Plated through-holes 402 provide an electrical connection between second conductive traces 245 and third conductive traces 265.

At this stage, as shown in FIG. 4F, three-dimensional semiconductor assembly 140 is accomplished, in which chip 75 is packaged in cavity 37 of cavity substrate that is electrically connected to top build-up circuitry 204 through plated through-holes 402. In this illustration, the cavity substrate includes stiffener 31, adhesive 141, electrical pads 13 and bottom build-up circuitry 203. Bottom build-up circuitry 203 includes first insulating layer 221, first conductive traces 225, second insulating layer 241 and second conductive traces 245, and top build-up circuitry 204 includes third insulating layer 261 and third conductive traces 265. Plated through-holes 402 are essentially shared by the cavity substrate and top build-up circuitry 204 and provide an electrical connection between them.

### Embodiment 5

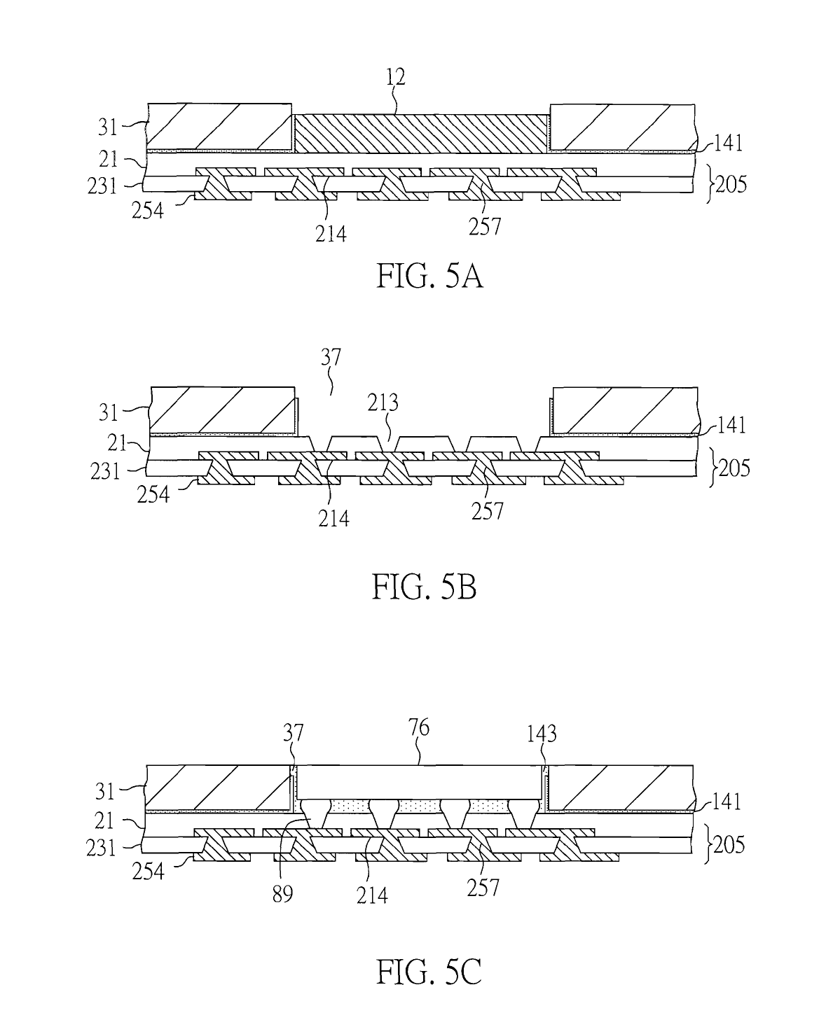

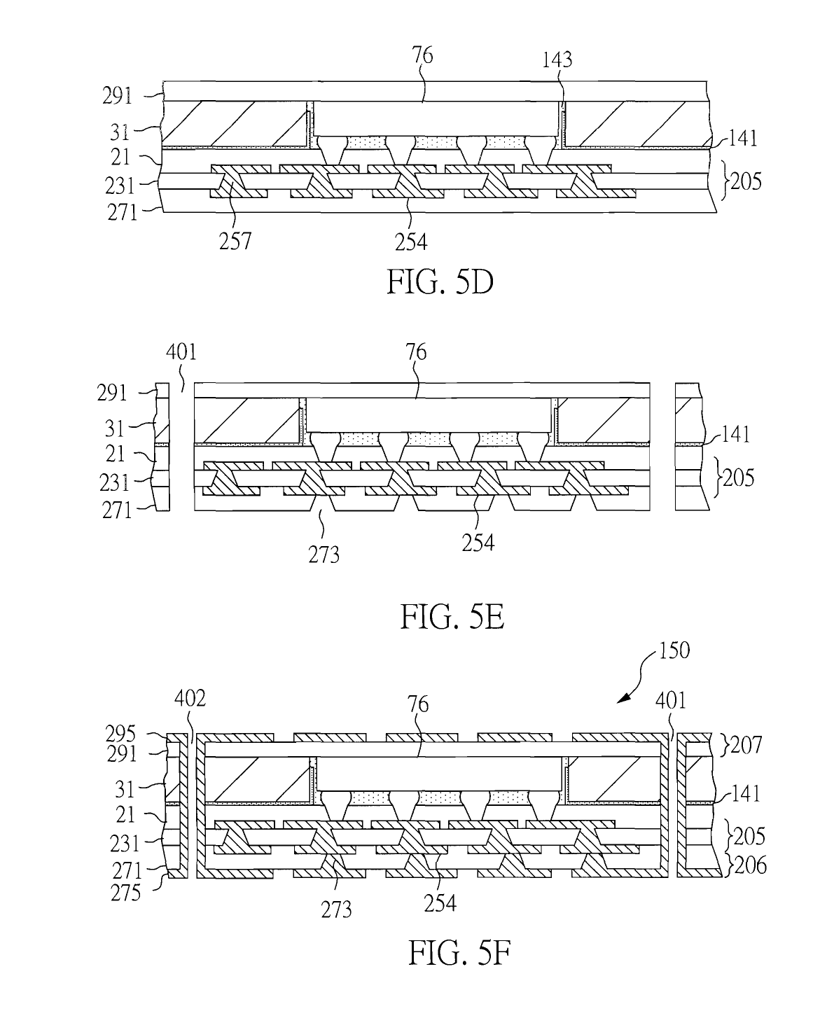

FIGS. 5A-5F are cross-sectional views showing a method of making a three-dimensional semiconductor assembly that includes a stiffener, an adhesive, a dielectric layer, a semiconductor device, an interconnect substrate, dual build-up circuitries and plated through-holes in accordance with another embodiment of the present invention.

For purposes of brevity, any description in above Embodiments is incorporated herein insofar as the same is applicable, and the same description need not be repeated.

FIG. 5A is a cross-sectional view of the structure, which is manufactured by the steps shown in FIGS. 3A-3C. All elements illustrated in this embodiment are the same as those mentioned in Embodiment 3, except that stiffener 31 includes no conductive layer thereon. In this illustration, interconnect substrate 205 includes first circuitry layer 214, first insulating layer 231, first conductive vias 257 and second circuitry layer 254.

FIG. 5B is a cross-sectional view of the structure with first circuitry layer 214 of interconnect substrate 205 exposed from cavity 37. Metal block 12 is removed to expose dielectric layer 21 and then via openings 213 are formed through dielectric layer 21 to expose selected portions of first circuitry layer 214 from cavity 37.

FIG. 5C is a cross-sectional view of the structure with chip 76 packaged in cavity 37 and under-fill 143 dispensed within cavity 37. Chip 76 extends into cavity 37 and is electrically coupled to first circuitry layer 214 through solder bumps 89.

FIG. 5D is a cross-sectional view of the structure provided with first build-up insulating layer 271 and second build-up insulating layer 291 on bottom and top surfaces. First build-up insulating layer 271 covers first insulating layer 231 and second circuitry layer 254 in the downward direction. Second build-up insulating layer 291 covers chip 76, stiffener 31 and under-fill 143 in the upward direction. Preferably, first build-up insulating layer 271 and second build-up insulating layer 291 are the same material deposited simultaneously in the same manner and have the same thickness.

FIG. 5E is a cross-sectional view of the structure provided with through-holes 401 and via openings 273. Through-holes 401 extend through second build-up insulating layer 291, stiffener 31, adhesive 141, dielectric layer 21, first insulating layer 231 and first build-up insulating layer 271 in vertical directions. Via openings 273 extend through first build-up insulating layer 271 to expose selected portions of second circuitry layer 254.

Referring now to FIG. 5F, first and second conductive traces 275, 295 are formed on first and second build-up insulating layers 271, 291. First conductive traces 275 extend from first build-up insulating layer 271 in the downward direction, extend laterally on first build-up insulating layer 271 and extend into via openings 273 in the upward direction to make electrical contact with second circuitry layer 254. Second conductive traces 295 extend from second build-up insulating layer 291 in the upward direction and extend laterally on second build-up insulating layer 291.

Also shown in FIG. 5F are plated through-holes 402 formed by depositing a connecting layer in through-hole 401. Plated through-holes 402 provide an electrical connection between first conductive traces 275 and second conductive traces 295.

At this stage, as shown in FIG. 5F, three-dimensional semiconductor assembly 150 is accomplished, in which chip 76 is packaged in cavity 37 of cavity substrate that is electrically connected to top build-up circuitry 207 through plated through-holes 402. In this illustration, the cavity substrate includes stiffener 31, adhesive 141, dielectric layer 21, interconnect substrate 205 and bottom build-up circuitry 206. Bottom build-up circuitry 206 includes first build-up insulating layer 271 and first conductive traces 275, and the top build-up circuitry 207 includes second build-up insulating layer 291 and second conductive traces 295. Plated through-holes 402 are essentially shared by the cavity substrate and top build-up circuitry 207 and provide an electrical connection between them.

The cavity substrates, stackable semiconductor assemblies and 3D stacking structures described above are merely exemplary. Numerous other embodiments are contemplated. In addition, the embodiments described above can be mixed-and-matched with one another and with other embodiments depending on design and reliability considerations. For instance, the stiffener can include ceramic material or epoxy-based laminate, and can have embedded single-level conductive traces or multi-level conductive traces. The sacrificial carrier can be processed into multiple metal blocks to cover multiple predetermined areas for creating multiple cavities. Accordingly, the cavity substrate can include multiple cavities arranged in an array for multiple semiconductor devices, and the build-up circuitry or the interconnect substrate can includes additional circuitries to accommodate additional semiconductor devices.

The semiconductor device can share or not share the cavity with other semiconductor devices. For instance, a single semiconductor device can be mounted into the built-in cavity. Alternatively, numerous semiconductor devices can be mounted into the built-in cavity. For instance, four small chips in a 2×2 array can be placed in the built-in cavity and additional electrical contacts can be provided at the cavity for additional chips. This may be more cost effective than providing a miniature cavity for each chip.

The semiconductor device can be a packaged or unpackaged chip. Furthermore, the semiconductor device can be a bare chip, LGA, or QFN, etc. The semiconductor device can be mechanically and electrically connected to the cavity substrate using a wide variety of connection media including solder. The built-in cavity can be customized for the semiconductor device embedded therein. For instance, the cavity can have a square or rectangular shape at its bottom with the same or similar topography as the semiconductor device.

The stiffener can provide a robust mechanical support for the build-up circuitry or the interconnect substrate, and the build-up circuitry or the interconnect substrate provides shorten signal routing so that signal loss and distortion can be reduced under accelerated operation of the semiconductor device.

The term “adjacent” refers to elements that are integral (single-piece) or in contact (not spaced or separated from) with one another. For instance, the terminal is adjacent to the connecting layer of the plated through-hole but not the conductive traces of the build-up circuitry.

The term “overlap” refers to above and extending within a periphery of an underlying element. Overlap includes extending inside and outside the periphery or residing within the periphery. For instance, in the cavity-up position, the stiffener overlaps the dielectric layer since an imaginary vertical line intersects the stiffener and the dielectric layer, regardless of whether another element such as the adhesive is between the stiffener and the dielectric layer and is intersected by the line, and regardless of whether another imaginary vertical line intersects the dielectric layer but not the stiffener (within the aperture of the stiffener). Likewise, the adhesive overlaps the dielectric layer, the stiffener overlaps the adhesive and the stiffener is overlapped by the adhesive. Moreover, overlap is synonymous with over and overlapped by is synonymous with under or beneath.

The term “contact” refers to direct contact. For instance, the stiffener contacts the adhesive but does not contact the interconnect substrate.

The term “cover” refers to incomplete and complete coverage in a vertical and/or lateral direction. For instance, in the cavity-up position, the adhesive covers the dielectric layer but does not cover the electrical pad in the upward direction.

The term “layer” refers to patterned and un-patterned layers. For instance, the conductive layer can be an un-patterned blanket sheet on the substrate when the stiffener including the conductive layer and the substrate is mounted on the adhesive. Furthermore, a layer can include stacked layers.

The terms “opening” and “aperture” and “hole” refer to a through hole and are synonymous. For instance, in the position that the dielectric layer covers the metal block in the downward direction, the metal block is exposed by the stiffener in the upward direction when it is inserted into the aperture of the stiffener.

The term “inserted” refers to relative motion between elements. For instance, the metal block is inserted into the aperture regardless of whether the dielectric layer is stationary and the stiffener moves towards the dielectric layer, the stiffener is stationary and the dielectric layer moves towards the stiffener or the dielectric layer and the stiffener both approach the other. Furthermore, the metal block is inserted (or extends) into the aperture regardless of whether it goes through (enters and exits) or does not go through (enters without exiting) the aperture.

The phrase “move towards one another” also refers to relative motion between elements. For instance, the dielectric layer and the stiffener move towards one another regardless of whether the dielectric layer is stationary and the stiffener moves towards the dielectric layer, the stiffener is stationary and the dielectric layer moves towards the stiffener or the dielectric layer and the stiffener both approach the other.

The phrase “aligned with” refers to relative position between elements. For instance, when the stiffener is mounted on the dielectric layer, the metal block is aligned with and inserted into the aperture and the electrical pad is aligned with, below and spaced from the aperture of the stiffener.

The phrases “mounted on”, “attached onto”, “attaching . . . onto”, “laminated onto” and “laminating . . . onto” include contact and non-contact with a single or multiple support element(s). For instance, the heat sink can be mounted on the semiconductor device regardless of whether it contacts the semiconductor device or is separated from the semiconductor device by an adhesive.

The phrase “adhesive . . . in the gap” refers to the adhesive in the gap. For instance, adhesive that contacts and is sandwiched between the metal block and the stiffener in the gap refers to the adhesive in the gap that contacts and is sandwiched between the metal block at the inner sidewall of the gap and the stiffener at the outer sidewall of the gap.

The phrase “electrical connection” or “electrically connects” or “electrically connected” refers to direct and indirect electrical connection. For instance, the plated through-hole provides an electrical connection for the first circuitry layer regardless of whether it is adjacent to the first circuitry layer or electrically connected to the first circuitry layer by the second circuitry layer.

The term “above” refers to upward extension and includes adjacent and non-adjacent elements as well as overlapping and non-overlapping elements. For instance, in the position that the dielectric layer covers the metal block in the downward direction, the metal block extends above, is adjacent to and protrudes from the dielectric layer.

The term “below” refers to downward extension and includes adjacent and non-adjacent elements as well as overlapping and non-overlapping elements. For instance, in the cavity-up position, the electrical pad extends below, is adjacent to and protrudes from the closed end of the cavity in the downward direction. Likewise, the electrical pad extends below the stiffener even though it is not adjacent to or overlapped by the stiffener.

The “first vertical direction” and “second vertical direction” do not depend on the orientation of the cavity substrate, as will be readily apparent to those skilled in the art. For instance, the build-up circuitry or the interconnect substrate covers the cavity in the first vertical direction and the cavity faces in the second vertical direction regardless of whether the cavity substrate is inverted. Likewise, the dielectric layer extends “laterally” to peripheral edges of the cavity substrate in a lateral plane regardless of whether the cavity substrate is inverted, rotated or slanted. Thus, the first and second vertical directions are opposite one another and orthogonal to the lateral directions, and laterally aligned elements are coplanar with one another at a lateral plane orthogonal to the first and second vertical directions. Furthermore, the first vertical direction is the downward direction and the second vertical direction is the upward direction in the cavity-up position, and the first vertical direction is the upward direction and the second vertical direction is the downward direction in the cavity-down position.

The cavity substrate and the semiconductor assembly using the same according to the present invention have numerous advantages. The cavity substrate and the semiconductor assembly are reliable, inexpensive and well-suited for high volume manufacture. A heat sink can be attached on the device mounted into the built-in cavity of the cavity substrate to facilitate heat dissipation. Therefore, the cavity substrate is especially well-suited for high power semiconductor devices and large semiconductor chips as well as multiple semiconductor devices such as small semiconductor chips in arrays which generate considerable heat and require excellent heat dissipation in order to operate effectively and reliably.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional packaging techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

Various changes and modifications to the embodiments described herein will be apparent to those skilled in the art. For instance, the materials, dimensions, shapes, sizes, steps and arrangement of steps described above are merely exemplary. Such changes, modifications and equivalents may be made without departing from the spirit and scope of the present invention as defined in the appended claims.

What is claimed is:

1. A method of making a cavity substrate, comprising:
providing a sacrificial carrier and an electrical pad that extends from the sacrificial carrier in a first vertical direction;
providing a dielectric layer that covers the sacrificial carrier and the electrical pad in the first vertical direction;
removing a selected portion of the sacrificial carrier with a remaining portion of the sacrificial carrier covering the electrical pad and a predetermined area for creating a cavity in a second vertical direction opposite the first vertical direction;
attaching a stiffener to the dielectric layer from the second vertical direction, including aligning the remaining portion of the sacrificial carrier within an aperture of the stiffener;
forming a build-up circuitry that covers the sacrificial carrier and the electrical pad in the first vertical direction and is electrically connected to the electrical pad; and
removing the remaining portion of the sacrificial carrier to form the cavity and exposing the electrical pad and portion of the build-up circuitry at a closed end of the cavity from the second vertical direction, wherein the cavity is laterally covered and surrounded by the stiffener and faces in the second vertical direction.

2. The method of claim 1, wherein forming the build-up circuitry includes:
providing a first insulating layer that includes the dielectric layer and covers the sacrificial carrier and the electrical pad in the first vertical direction; then
forming a first via opening that extends through the first insulating layer and is aligned with the electrical pad; and then
forming a first conductive trace that extends from the first insulating layer in the first vertical direction and extends laterally on the first insulating layer and extends through the first via opening in the second vertical direction to form a first conductive via in contact with the electrical pad.

3. The method of claim 1, further comprising providing a plated through-hole that extends through the stiffener to provide an electrical connection between both sides of the cavity substrate.

4. The method of claim 3, wherein providing the plated through-hole includes:
forming a through-hole that extends through the stiffener in the vertical directions; and then
providing a connecting layer on an inner sidewall of the through-hole.

5. The method of claim 1, wherein removing the sacrificial carrier includes chemical etching process.

6. A method of making a cavity substrate, comprising:
providing a sacrificial carrier;
providing a dielectric layer that covers the sacrificial carrier in a first vertical direction;
removing a selected portion of the sacrificial carrier with a remaining portion of the sacrificial carrier covering a predetermined area for creating a cavity in a second vertical direction opposite the first vertical direction;
attaching a stiffener to the dielectric layer from the second vertical direction, including aligning the remaining portion of the sacrificial carrier within an aperture of the stiffener;
forming a build-up circuitry that covers the sacrificial in the first vertical direction; and
removing the remaining portion of the sacrificial carrier to form the cavity and exposing portion of the build-up circuitry at a closed end of the cavity from the second vertical direction, wherein the cavity is laterally covered and surrounded by the stiffener and faces in the second vertical direction.

7. The method of claim 6, wherein exposing portion of the build-up circuitry includes exposing a first conductive via of the build-up circuitry.

8. The method of claim 7, wherein forming the build-up circuitry includes:
providing a first insulating layer that includes the dielectric layer and covers the sacrificial carrier in the first vertical direction; then
forming a first via opening that extends through the first insulating layer and is aligned with the sacrificial carrier; and then
forming a first conductive trace that extends from the first insulating layer in the first vertical direction and extends laterally on the first insulating layer and extends through the first via opening in the second vertical direction to form the first conductive via in contact with the sacrificial carrier.

9. The method of claim 6, further comprising providing a plated through-hole that extends through the stiffener to provide an electrical connection between both sides of the cavity substrate.

10. The method of claim 9, wherein providing the plated through-hole includes:
forming a through-hole that extends through the stiffener in the vertical directions; and then
providing a connecting layer on an inner sidewall of the through-hole.

11. The method of claim 6, wherein removing the sacrificial carrier includes chemical etching process.

12. A method of making a cavity substrate, comprising:
providing a sacrificial carrier;
attaching an interconnect substrate to the sacrificial carrier using a dielectric layer that covers the sacrificial carrier in a first vertical direction and covers the interconnect substrate in a second vertical direction opposite the first vertical direction;
removing a selected portion of the sacrificial carrier with a remaining portion of the sacrificial carrier covering a predetermined area for creating a cavity in the second vertical direction;
attaching a stiffener to the dielectric layer from the second vertical direction, including aligning the remaining portion of the sacrificial carrier within an aperture of the stiffener;
removing the remaining portion of the sacrificial carrier to form the cavity and exposing portion of the dielectric layer at a closed end of the cavity from the second vertical direction, wherein the cavity is laterally covered and surrounded by the stiffener and faces in the second vertical direction; and
forming a via opening in the dielectric layer to expose a selected portion of the interconnect substrate at the closed end of the cavity from the second vertical direction.

13. The method of claim 12, further comprising forming a conductive via in the via opening.

14. The method of claim 12, further comprising providing a plated through-hole that extends through the stiffener to provide an electrical connection between both sides of the cavity substrate.

15. The method of claim 14, wherein providing the plated through-hole includes:
forming a through-hole that extends through the stiffener in the vertical directions; and then
providing a connecting layer on an inner sidewall of the through-hole.

16. The method of claim 11, wherein removing the sacrificial carrier includes chemical etching process.
